(19) United States
(12) Patent Application Publication
(10) Pub. No.: US 2020/0058683 A1
(43) Pub. Date: Feb. 20, 2020

(54) LIQUID CRYSTAL DISPLAY DEVICE, ORGANIC EL DISPLAY DEVICE, SEMICONDUCTOR ELEMENT, WIRING FILM, WIRING SUBSTRATE, AND TARGET

(71) Applicant: ULVAC, INC., Chigasaki-shi (JP)

(72) Inventors: Satoru TAKASAWA, Chiba-shi (JP); Yasuo NAKADAI, Inzai-shi (JP); Junichi NITTA, Sanmu-shi (JP); Satoru ISHIBASHI, Sanmu-shi (JP)

(73) Assignee: ULVAC, INC., Chigasaki-shi (JP)

(21) Appl. No.: 16/587,636

(22) Filed: Sep. 30, 2019

Related U.S. Application Data
(63) Continuation of application No. PCT/JP2017/046927, filed on Dec. 27, 2017.

(30) Foreign Application Priority Data
Apr. 13, 2017 (JP) 2017-079991

(51) Int. Cl. H01L 27/12; G02F 1/1368; G02F 1/1362; H01L 27/32; H01L 23/498; H01L 29/49; H01L 29/66; C23C 14/34; H01J 37/34

(52) U.S. Cl. CPC H01L 27/1244; G02F 1/1368; G02F 1/136286; H01L 27/3279; H01L 23/49866; G02F 2001/136295; H01L 29/66742; H01L 27/1259; C23C 14/3407; H01J 37/3426; H01L 29/4908

(57) ABSTRACT

A wiring film capable of being patterned by a single etching process and has strong adhesion force to a resin substrate, and a semiconductor element and a display device that uses the wiring film, are disclosed. Since a base film that is in contact with a resin substrate is a copper thin film containing, at a predetermined ratio, aluminum as a main additive metal and silicon, titanium or nickel as a secondary additive metal, and has strong adhesion force to resins, wiring films (a gate electrode layer) do not separate from the resin substrate. Also, since the base film and a low resistance film contain a large amount of copper, the base film and the low resistance film may be etched together by means of an etchant or an etching gas by which copper is etched, therefore, the wiring films are able to be patterned by a single etching process.

### TECHNICAL FIELD

The present invention relates to a technical field of a wiring film used in a micro semiconductor device, and more particularly, to a technical field of an electrode layer in contact with a resin.

### BACKGROUND

In the related art, a display portion of a flat panel display (FPD) has been formed on a glass substrate, but in recent years, a technique for forming a display portion on a substrate on a surface of which a resin is exposed, such as a film or a resin substrate, has been demanded.

A wiring film of the FPD is formed on the glass substrate by a sputtering method, but in a case where the wiring film is formed on the resin substrate having flexibility and bendability instead of the glass substrate, adhesion between a copper thin film used as the wiring film due to low resistance characteristics and the resin substrate is poor, and the wiring film is peeled from the resin substrate, such that defective products are easily generated.

When a primer layer such as a titanium thin film or a chromium thin film is provided between the copper thin film and the resin substrate to configure a wiring film having a two-layer structure, adhesion between the wiring film and the resin substrate is improved. However, it is difficult to adopt the titanium thin film or the chromium thin film in a mass production process because an etchant and an etching gas for patterning the primer layer is different from an etchant and an etching gas for patterning the wiring film. Therefore, a technique for improving the adhesion between the copper thin film and the resin substrate without increasing the number of processes has been demanded.

### SUMMARY

An object of the present embodiment is to provide a wiring film that is difficult to peel from a resin substrate and that can be patterned by one type of etchant or etching gas.

In order to solve the above-mentioned problem, the present embodiment provides a liquid crystal display device comprising a resin substrate, a semiconductor element, a liquid crystal layer and a polarizing filter, wherein a voltage applied to the liquid crystal layer is changed by conduction and interruption of the semiconductor element to control penetration of light that penetrated the liquid crystal layer through the polarizing filter, wherein the semiconductor element includes a semiconductor layer, a gate insulating film that is in contact with the semiconductor layer, a gate electrode layer that faces the semiconductor layer with the gate insulating film interposed therebetween and that is in contact with the gate insulating film, and first and second electrode layers that are electrically connected to the semiconductor layer by contacting with the semiconductor layer, and electrical conduction and interruption between the first electrode layer and the second electrode layer are controlled by a voltage applied to the gate electrode layer, one or more of the gate electrode layer, the first electrode layer, and the second electrode layer are electrically connected to a wiring film that is in contact with the resin substrate, the wiring film includes a base film that is in contact with the resin substrate and a low resistance film that is in contact with the base film and that has a resistivity lower than that of the base film, among elements constituting the base film, copper is contained in the largest mass ratio in the base film, aluminum is contained as a main additive metal in a range of 1.0 wt % or more to 8.0 wt % or less, silicon is contained as a sub-additive metal in a range of 1.0 wt % or more to 8.0 wt % or less, components that are included in the base film and that are other than the main additive metal and the sub-additive metal are copper and inevitable impurities, and the inevitable impurities are contained in a range of 1 wt % or less, in 100 wt % of the base film, and a mass ratio of copper of the low resistance film is higher than that of the base film.

The present embodiment provides a liquid crystal display device comprising a resin substrate, a semiconductor element, a liquid crystal layer, and a polarizing filter, wherein a voltage applied to the liquid crystal layer is changed by conduction and interruption of the semiconductor element to control penetration of light that penetrated the liquid crystal layer through the polarizing filter, wherein the semiconductor element includes a semiconductor layer, a gate insulating film that is in contact with the semiconductor layer, a gate electrode layer that faces the semiconductor layer with the gate insulating film interposed therebetween and that is in contact with the gate insulating film, and first and second electrode layers that are electrically connected to the semiconductor layer by contacting with the semiconductor layer, and electrical conduction and interruption between the first electrode layer and the second electrode layer are controlled by a voltage applied to the gate electrode layer, one or more of the gate electrode layer, the first electrode layer, and the second electrode layer are electrically connected to a wiring film that is in contact with the resin substrate, the wiring film includes a base film that is in contact with the resin substrate and a low resistance film that is in contact with the base film and that has a resistivity lower than that of the base film, among elements constituting the base film, copper is contained in the largest mass ratio in the base film, aluminum is contained as a main additive metal in a range of 1.0 wt % or more to 8.0 wt % or less, titanium is contained as a sub-additive metal in a range of 1.0 wt % or more to 4.0 wt % or less, components that are included in the base film and that are other than the main additive metal and the sub-additive metal are copper and inevitable impurities, and the inevitable impurities are contained in a range of 1 wt % or less, in 100 wt % of the base film, and a mass ratio of copper of the low resistance film is higher than that of the base film.

Further, the present embodiment provides a liquid crystal display device comprising a resin substrate, a semiconductor element, a liquid crystal layer and a polarizing filter, wherein a voltage applied to the liquid crystal layer is changed by conduction and interruption of the semiconductor element to control penetration of light that penetrated the liquid crystal layer through the polarizing filter, wherein the semiconductor element includes a semiconductor layer, a gate insulating film that is in contact with the semiconductor layer, a gate electrode layer that faces the semiconductor layer with the gate insulating film interposed therebetween and that is in contact with the gate insulating film, and first and second electrode layers that are electrically connected to the semiconductor layer by contacting with the semiconductor layer, and electrical conduction and interruption between the first electrode layer and the second electrode layer are controlled by a voltage applied to the gate electrode layer, one or more of the gate electrode layer, the first electrode layer, and the second electrode layer are electrically connected to a wiring film that is in contact with the resin substrate, the wiring film includes a base film that is in contact with the resin substrate and a low resistance film that is in contact with the base film and that has a resistivity lower than that of the base film, any one of copper and a sub-additive metal among elements constituting the base film is contained in the largest mass ratio in the base film, aluminum is contained as a main additive metal in a range of 1.0 wt % or more to 8.0 wt % or less, nickel is contained as the sub-additive metal in a range of 10 wt % or more to 50 wt % or less, components that are included in the base film and that are other than the main additive metal and the sub-additive metal are copper and inevitable impurities, and the inevitable impurities are contained in a range of 1 wt % or less, in 100 wt % of the base film, and a mass ratio of copper of the low resistance film is higher than that of the base film.

The present embodiment provides a liquid crystal display device comprising a glass substrate, a semiconductor element, a liquid crystal layer and a polarizing filter, wherein a voltage applied to the liquid crystal layer is changed by conduction and interruption of the semiconductor element to control penetration of light that penetrated the liquid crystal layer through the polarizing filter, wherein the semiconductor element includes a semiconductor layer, a gate insulating film that is in contact with the semiconductor layer, a gate electrode layer that faces the semiconductor layer with the gate insulating film interposed therebetween and that is in contact with the gate insulating film, and first and second electrode layers that are electrically connected to the semiconductor layer by contacting with the semiconductor layer, and electrical conduction and interruption between the first electrode layer and the second electrode layer are controlled by a voltage applied to the gate electrode layer, one or more of the gate electrode layer, the first electrode layer, and the second electrode layer are electrically connected to a wiring film that is in contact with the glass substrate, the wiring film includes a base film that is in contact with the glass substrate and a low resistance film that is in contact with the base film and that has a resistivity lower than that of the base film, among elements constituting the base film, copper is contained in the largest mass ratio in the base film, aluminum is contained as a main additive metal in a range of 0.5 wt % or more to 8.0 wt % or less, silicon is contained as a sub-additive metal in a range of 0.5 wt % or more to 8.0 wt % or less, components that are included in the base film and that are other than the main additive metal and the sub-additive metal are copper and inevitable impurities, and the inevitable impurities are contained in a range of 1 wt % or less, in 100 wt % of the base film, and a mass ratio of copper of the low resistance film is higher than that of the base film.

The present embodiment provides an organic electroluminescence (EL) display device comprising a resin substrate, a semiconductor element, and an organic EL layer, wherein a voltage applied to the organic EL layer is changed by controlling the semiconductor element, such that a magnitude of a current flowing through the organic EL layer is controlled, wherein the semiconductor element includes a semiconductor layer, a gate insulating film that is in contact with the semiconductor layer, a gate electrode layer that faces the semiconductor layer with the gate insulating film interposed therebetween and that is in contact with the gate insulating film, and first and second electrode layers that are electrically connected to the semiconductor layer by contacting with the semiconductor layer, and electrical conduction and interruption between the first electrode layer and the second electrode layer are controlled by a voltage applied to the gate electrode layer, one or more of the gate electrode layer, the first electrode layer, and the second electrode layer are electrically connected to a wiring film that is in contact with the resin substrate, the wiring film includes a base film that is in contact with the resin substrate and a low resistance film that is in contact with the base film and that has a resistivity lower than that of the base film, among elements constituting the base film, copper is contained in the largest mass ratio in the base film, aluminum is contained as a main additive metal in a range of 1.0 wt % or more to 8.0 wt % or less, silicon is contained as a sub-additive metal in a range of 1.0 wt % or more to 8.0 wt % or less, components that are included in the base film and that are other than the main additive metal and the sub-additive metal are copper and inevitable impurities, and the inevitable impurities are contained in a range of 1 wt % or less, in 100 wt % of the base film, and a mass ratio of copper of the low resistance film is higher than that of the base film.

The present embodiment provides an organic EL display device comprising a resin substrate, a semiconductor element, and an organic EL layer, wherein a voltage applied to the organic EL layer is changed by controlling the semiconductor element, such that a magnitude of a current flowing through the organic EL layer is controlled, wherein the semiconductor element includes a semiconductor layer, a gate insulating film that is in contact with the semiconductor layer, a gate electrode layer that faces the semiconductor layer with the gate insulating film interposed therebetween and that is in contact with the gate insulating film, and first and second electrode layers that are electrically connected to the semiconductor layer by contacting with the semiconductor layer, and electrical conduction and interruption between the first electrode layer and the second electrode layer are controlled by a voltage applied to the gate electrode layer, one or more of the gate electrode layer, the first electrode layer, and the second electrode layer are electrically connected to a wiring film that is in contact with the resin substrate, the wiring film includes a base film that is in contact with the resin substrate and a low resistance film that is in contact with the base film and that has a resistivity lower than that of the base film, among elements constituting the base film, copper is contained in the largest mass ratio in the base film, aluminum is contained as a main additive metal in a range of 1.0 wt % or more to 8.0 wt % or less, titanium is contained as a sub-additive metal in a range of 1.0 wt % or more to 4.0 wt % or less, components that are included in the base film and that are other than the main additive metal and the sub-additive metal are copper and inevitable impurities, and the inevitable impurities are contained in a range of 1 wt % or less, in 100 wt % of the base film, and a mass ratio of copper of the low resistance film is higher than that of the base film.

Further, the present embodiment provides an organic EL display device comprising a resin substrate, a semiconductor element, and an organic EL layer, wherein a voltage applied to the organic EL layer is changed by controlling the semiconductor element, such that a magnitude of a current flowing through the organic EL layer is controlled, wherein the semiconductor element includes a semiconductor layer, a gate insulating film that is in contact with the semiconductor layer, a gate electrode layer that faces the semiconductor layer with the gate insulating film interposed therebetween and that is in contact with the gate insulating film, and first and second electrode layers that are electrically connected to the semiconductor layer by contacting with the semiconductor layer, and electrical conduction and interruption between the first electrode layer and the second electrode layer are controlled by a voltage applied to the gate electrode layer, one or more of the gate electrode layer, the first electrode layer, and the second electrode layer are electrically connected to a wiring film that is in contact with the resin substrate, the wiring film includes a base film that is in contact with the resin substrate and a low resistance film that is in contact with the base film and that has a resistivity lower than that of the base film, any one of copper and a sub-additive metal among elements constituting the base film is contained in the largest mass ratio in the base film, aluminum is contained as a main additive metal in a range of 1.0 wt % or more to 8.0 wt % or less, nickel is contained as the sub-additive metal in a range of 10 wt % or more to 50 wt % or less, components that are included in the base film and that are other than the main additive metal and the sub-additive metal are copper and inevitable impurities, and the inevitable impurities are contained in a range of 1 wt % or less, in 100 wt % of the base film, and a mass ratio of copper of the low resistance film is higher than that of the base film.

The present embodiment provides an organic EL display device comprising a glass substrate, a semiconductor element, and an organic EL layer, wherein a voltage applied to the organic EL layer is changed by controlling the semiconductor element, such that a magnitude of a current flowing through the organic EL layer is controlled, wherein the semiconductor element includes a semiconductor layer, a gate insulating film that is in contact with the semiconductor layer, a gate electrode layer that faces the semiconductor layer with the gate insulating film interposed therebetween and that is in contact with the gate insulating film, and first and second electrode layers that are electrically connected to the semiconductor layer by contacting with the semiconductor layer, and electrical conduction and interruption between the first electrode layer and the second electrode layer are controlled by a voltage applied to the gate electrode layer, one or more of the gate electrode layer, the first electrode layer, and the second electrode layer are electrically connected to a wiring film that is in contact with the glass substrate, the wiring film includes a base film that is in contact with the glass substrate and a low resistance film that is in contact with the base film and that has a resistivity lower than that of the base film, among elements constituting the base film, copper is contained in the largest mass ratio in the base film, aluminum is contained as a main additive metal in a range of 0.5 wt % or more to 8.0 wt % or less, silicon is contained as a sub-additive metal in a range of 0.5 wt % or more to 8.0 wt % or less, components that are included in the base film and that are other than the main additive metal and the sub-additive metal are copper and inevitable impurities, and the inevitable impurities are contained in a range of 1 wt % or less, in 100 wt % of the base film, and a mass ratio of copper of the low resistance film is higher than that of the base film.

The present embodiment provides a semiconductor element comprising a semiconductor layer, a gate insulating film that is in contact with the semiconductor layer, a gate electrode layer that faces the semiconductor layer with the gate insulating film interposed therebetween and that is in contact with the gate insulating film and first and second electrode layers that are electrically connected to the semiconductor layer by contacting with the semiconductor layer, wherein electrical conduction and interruption between the first electrode layer and the second electrode layer are controlled by a voltage applied to the gate electrode layer, one or more of the gate electrode layer, the first electrode layer, and the second electrode layer are electrically connected to a wiring film that is in contact with a resin substrate, the wiring film includes a base film that is in contact with the resin substrate and a low resistance film that is in contact with the base film and that has a resistivity lower than that of the base film, among elements constituting the base film, copper is contained in the largest mass ratio in the base film, aluminum is contained as a main additive metal in a range of 1.0 wt % or more to 8.0 wt % or less, silicon is contained as a sub-additive metal in a range of 1.0 wt % or more to 8.0 wt % or less, components that are included in the base film and that are other than the main additive metal and the sub-additive metal are copper and inevitable impurities, and the inevitable impurities are contained in a range of 1 wt % or less, in 100 wt % of the base film, and a mass ratio of copper of the low resistance film is higher than that of the base film.

The present embodiment provides a semiconductor element comprising a semiconductor layer, a gate insulating film that is in contact with the semiconductor layer, a gate electrode layer that faces the semiconductor layer with the gate insulating film interposed therebetween and that is in contact with the gate insulating film and first and second electrode layers that are electrically connected to the semiconductor layer by contacting with the semiconductor layer, wherein electrical conduction and interruption between the first electrode layer and the second electrode layer are controlled by a voltage applied to the gate electrode layer, one or more of the gate electrode layer, the first electrode layer, and the second electrode layer are electrically connected to a wiring film that is in contact with a resin substrate, the wiring film includes a base film that is in contact with the resin substrate and a low resistance film that is in contact with the base film and that has a resistivity lower than that of the base film, among elements constituting the base film, copper is contained in the largest mass ratio in the base film, aluminum is contained as a main additive metal in a range of 1.0 wt % or more to 8.0 wt % or less, titanium is contained as a sub-additive metal in a range of 1.0 wt % or more to 4.0 wt % or less, components that are included in the base film and that are other than the main additive metal and the sub-additive metal are copper and inevitable impurities, and the inevitable impurities are contained in a range of 1 wt % or less, in 100 wt % of the base film, and a mass ratio of copper of the low resistance film is higher than that of the base film.

The present embodiment provides a semiconductor element comprising a semiconductor layer, a gate insulating film that is in contact with the semiconductor layer, a gate electrode layer that faces the semiconductor layer with the gate insulating film interposed therebetween and that is in contact with the gate insulating film and first and second electrode layers that are electrically connected to the semiconductor layer by contacting with the semiconductor layer, wherein electrical conduction and interruption between the first electrode layer and the second electrode layer are controlled by a voltage applied to the gate electrode layer, one or more of the gate electrode layer, the first electrode layer, and the second electrode layer are electrically connected to a wiring film that is in contact with a resin substrate, the wiring film includes a base film that is in contact with the resin substrate and a low resistance film that is in contact with the base film and that has a resistivity lower than that of the base film, any one of copper and a sub-additive metal among elements constituting the base film is contained in the largest mass ratio in the base film, aluminum is contained as a main additive metal in a range of 1.0 wt % or more to 8.0 wt % or less, nickel is contained as the sub-additive metal in a range of 10 wt % or more to 50 wt % or less, components that are included in the base film and that are other than the main additive metal and the sub-additive metal are copper and inevitable impurities, and the inevitable impurities are contained in a range of 1 wt % or less, in 100 wt % of the base film, and a mass ratio of copper of the low resistance film is higher than that of the base film.

The present embodiment provides a wiring film fixed to a resin substrate comprising a base film that is in contact with the resin substrate and a low resistance film that is in contact with the base film and that has a resistivity lower than that of the base film, wherein among elements constituting the base film, copper is contained in the largest mass ratio in the base film, aluminum is contained as a main additive metal in a range of 1.0 wt % or more to 8.0 wt % or less, silicon is contained as a sub-additive metal in a range of 1.0 wt % or more to 8.0 wt % or less, components that are included in the base film and that are other than the main additive metal and the sub-additive metal are copper and inevitable impurities, and the inevitable impurities are contained in a range of 1 wt % or less, in 100 wt % of the base film, and a mass ratio of copper of the low resistance film is higher than that of the base film.

The present embodiment provides a wiring film fixed to a resin substrate, comprising a base film that is in contact with the resin substrate and a low resistance film that is in contact with the base film and that has a resistivity lower than that of the base film, wherein among elements constituting the base film, copper is contained in the largest mass ratio in the base film, aluminum is contained as a main additive metal in a range of 1.0 wt % or more to 8.0 wt % or less, titanium is contained as a sub-additive metal in a range of 1.0 wt % or more to 4.0 wt % or less, components that are included in the base film and that are other than the main additive metal and the sub-additive metal are copper and inevitable impurities, and the inevitable impurities are contained in a range of 1 wt % or less, in 100 wt % of the base film, and a mass ratio of copper of the low resistance film is higher than that of the base film.

The present embodiment provides a wiring film fixed to a resin substrate, comprising a base film that is in contact with the resin substrate and a low resistance film that is in contact with the base film and that has a resistivity lower than that of the base film, wherein any one of copper and a sub-additive metal among elements constituting the base film is contained in the largest mass ratio in the base film, aluminum is contained as a main additive metal in a range of 1.0 wt % or more to 8.0 wt % or less, nickel is contained as the sub-additive metal in a range of 10 wt % or more to 50 wt % or less, components that are included in the base film and that are other than the main additive metal and the sub-additive metal are copper and inevitable impurities, and the inevitable impurities are contained in a range of 1 wt % or less, in 100 wt % of the base film, and a mass ratio of copper of the low resistance film is higher than that of the base film.

The present embodiment provides a wiring film fixed to a glass substrate, comprising a base film that is in contact with the glass substrate and a low resistance film that is in contact with the base film and that has a resistivity lower than that of the base film, wherein among elements constituting the base film, copper is contained in the largest mass ratio in the base film, aluminum is contained as a main additive metal in a range of 0.5 wt % or more to 8.0 wt % or less, silicon is contained as a sub-additive metal in a range of 0.5 wt % or more to 8.0 wt % or less, components that are included in the base film and that are other than the main additive metal and the sub-additive metal are copper and inevitable impurities, and the inevitable impurities are contained in a range of 1 wt % or less, in 100 wt % of the base film, and a mass ratio of copper of the low resistance film is higher than that of the base film.

The present embodiment provides a wiring film fixed to a glass substrate in which a plurality of through-holes are formed, comprising a base film that is in contact with a surface of the glass substrate and inner peripheral surfaces of the through-holes and a low resistance film that is in contact with the base film and that has a resistivity lower than that of the base film, wherein among elements constituting the base film, copper is contained in the largest mass ratio in the base film, aluminum is contained as a main additive metal in a range of 0.5 wt % or more to 8.0 wt % or less, silicon is contained as a sub-additive metal in a range of 0.5 wt % or more to 8.0 wt % or less, components that are included in the base film and that are other than the main additive metal and the sub-additive metal are copper and inevitable impurities, and the inevitable impurities are contained in a range of 1 wt % or less, in 100 wt % of the base film, a mass ratio of copper of the low resistance film is higher than that of the base film, and in at least parts of the low resistance film, a part that is disposed on a front surface of the glass substrate and a part that is in contact with the base film in the through-holes and that fills the through-holes are in contact with each other.

The present embodiment provides a wiring substrate comprising a glass substrate in which a plurality of through-holes are formed, and a wiring film that is provided on the glass substrate, wherein the wiring film includes a base film that is in contact with a surface of the glass substrate and inner peripheral surfaces of the through-holes and a low resistance film that is in contact with the base film and that has a resistivity lower than that of the base film, among elements constituting the base film, copper is contained in the largest mass ratio in the base film, aluminum is contained as a main additive metal in a range of 0.5 wt % or more to 8.0 wt % or less, silicon is contained as a sub-additive metal in a range of 0.5 wt % or more to 8.0 wt % or less, components that are included in the base film and that are other than the main additive metal and the sub-additive metal are copper and inevitable impurities, and the inevitable impurities are contained in a range of 1 wt % or less, in 100 wt % of the base film, a mass ratio of copper of the low resistance film is higher than that of the base film, inner portions of the through-holes are filled with the low resistance film in contact with the base film in the through-holes, and in at least parts of the low resistance film, a part that is disposed on a front surface of the glass substrate and a part that is in contact with the base film in the through-holes and that fills the through-holes are in contact with each other.

The present embodiment provides a target of a sputtering device that forms a base film in contact with a resin substrate of a wiring film fixed to a resin substrate, wherein aluminum is contained as a main additive metal in a range of 1.0 wt % or more to 8.0 wt % or less, silicon is contained as a sub-additive metal in a range of 1.0 wt % or more to 8.0 wt % or less, and components that are included in the target and that are other than the main additive metal and the sub-additive metal are copper and inevitable impurities, and the inevitable impurities are contained in a range of 1 wt % or less, in 100 wt % of the target.

The present embodiment provides a target of a sputtering device that forms a base film in contact with a resin substrate of a wiring film fixed to a resin substrate, wherein aluminum is contained as a main additive metal in a range of 1.0 wt % or more to 8.0 wt % or less, titanium is contained as a sub-additive metal in a range of 1.0 wt % or more to 4.0 wt % or less, and components that are included in the target and that are other than the main additive metal and the sub-additive metal are copper and inevitable impurities, and the inevitable impurities are contained in a range of 1 wt % or less, in 100 wt % of the target.

The present embodiment provides a target of a sputtering device that forms a base film in contact with a resin substrate of a wiring film fixed to a resin substrate, wherein aluminum is contained as a main additive metal in a range of 1.0 wt % or more to 8.0 wt % or less, nickel is contained as a sub-additive metal in a range of 10 wt % or more to 50 wt % or less and, components that are included in the target and that are other than the main additive metal and the sub-additive metal are copper and inevitable impurities, and the inevitable impurities are contained in a range of 1 wt % or less, in 100 wt % of the target.

Since an adhesive force between a base layer and a resin substrate is large, a wiring film is not peeled from the resin substrate.

Since a content of copper in the base layer is large, the base layer and a low resistance layer disposed on the base layer can be patterned by the same etchant or etching gas.

Since a resistivity of the low resistance layer disposed on the base layer is small, a wiring film having a low resistance can be obtained.

### BRIEF DESCRIPTION OF DRAWINGS

FIG. 1 is a process diagram (1) for describing a manufacturing process of a transistor according to an embodiment of the present invention.

FIG. 2 is a process diagram (2) for describing a manufacturing process of a transistor according to an embodiment of the present invention.

FIG. 3 is a process diagram (3) for describing a manufacturing process of a transistor according to an embodiment of the present invention.

FIG. 4 is a process diagram (4) for describing a manufacturing process of a transistor according to an embodiment of the present invention.

FIG. 5 is a process diagram (5) for describing a manufacturing process of a transistor according to an embodiment of the present invention.

FIG. 6 is a process diagram (6) for describing a manufacturing process of a transistor according to an embodiment of the present invention.

FIG. 7 is a process diagram (7) for describing a manufacturing process of a transistor according to an embodiment of the present invention.

FIG. 8 is a process diagram (8) for describing a manufacturing process of a transistor according to an embodiment of the present invention.

FIG. 9 is a process diagram (9) for describing a manufacturing process of a transistor according to an embodiment of the present invention.

FIG. 10 is a process diagram (10) for describing a manufacturing process of a transistor according to an embodiment of the present invention.

FIG. 11 is a process diagram (11) for describing a manufacturing process of a transistor according to an embodiment of the present invention.

FIG. 12 is a process diagram (12) for describing a manufacturing process of a transistor according to an embodiment of the present invention.

FIG. 13 is a process diagram (13) for describing a manufacturing process of a transistor according to an embodiment of the present invention.

FIG. 14 is a process diagram (14) for describing a manufacturing process of a transistor according to an embodiment of the present invention.

FIG. 15 is a view showing an example of a film forming device.

FIG. 16 is a perspective view showing a position of a wiring film.

FIGS. 17(a) to 17(c) are views for describing processes of manufacturing a wiring substrate.

FIG. 18 is a view for describing a build-up substrate.

### DETAILED DESCRIPTION OF EMBODIMENTS

<Description of Display Device>

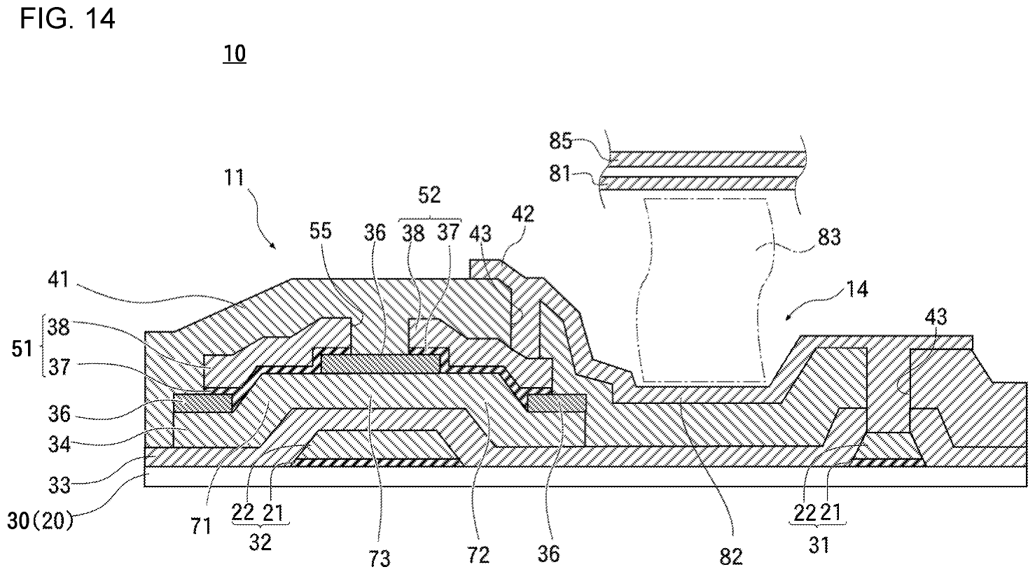

FIG. 14 shows a liquid crystal display device 10 as a display device according to an embodiment of the present invention, and the liquid crystal display device 10 includes a resin substrate 30, a semiconductor element 11, and a liquid crystal display portion 14. In FIG. 14, a cross-sectional view of the semiconductor element 11 is shown together with a cross-sectional view of the liquid crystal display portion 14.

The semiconductor element 11 includes two types of wiring films 31 and 32 formed together, a semiconductor layer 34, a first electrode layer 51 that is a source electrode layer, a second electrode layer 52 that is a drain electrode layer, and a pixel electrode layer 82. One type of wiring film 31 of the two types of wiring films 31 and 32 is electrically connected to at least one electrode layer of the first electrode layer 51, the second electrode layer 52, and the pixel electrode layer 82, and the other type of wiring film 32 of the two types of wiring films 31 and 32 is used as a gate electrode layer. The wiring film 32 used as the gate electrode layer is also referred to as a gate electrode layer 32. Positions of the wiring films 31 and 32 are shown in a perspective view of FIG. 16.

The resin substrate 30 is formed of a resin having flexibility and transparency, and at least parts of the wiring films 31 and 32 are provided in contact with the resin substrate 30 on a surface of the resin substrate 30.

The gate electrode layer 32 has one surface in contact with the resin substrate 30 and the other surface in contact with one surface of a gate insulating film 33, and the semiconductor layer 34 is disposed in contact with the gate insulating film 33 on the other surface of the gate insulating film 33. In this structure, the gate insulating film 33 is positioned between the gate electrode layer 32 and the semiconductor layer 34, and the gate electrode layer 32 is covered with the gate insulating film 33 so that the gate electrode layer 32 and the semiconductor layer 34 are not in contact with each other.

The first electrode layer 51 and the second electrode layer 52 are disposed in contact with the semiconductor layer 34.

The first electrode layer 51 and the second electrode layer 52 include an oxygen diffusion preventing layer 37 formed in contact with the semiconductor layer 34 and an upper electrode layer 38 formed in contact with the oxygen diffusion preventing layer 37 and having a low resistivity. Since it is preferable that the upper electrode layer 38 is not in contact with the semiconductor layer 34, the oxygen diffusion preventing layer 37 is disposed between the upper electrode layer 38 and the semiconductor layer 34. The oxygen diffusion preventing layer 37 is also called a barrier film, and a titanium thin film or an oxygen-containing copper thin film can be used as the oxygen diffusion preventing layer 37. A copper thin film can be used as the upper electrode layer 38.

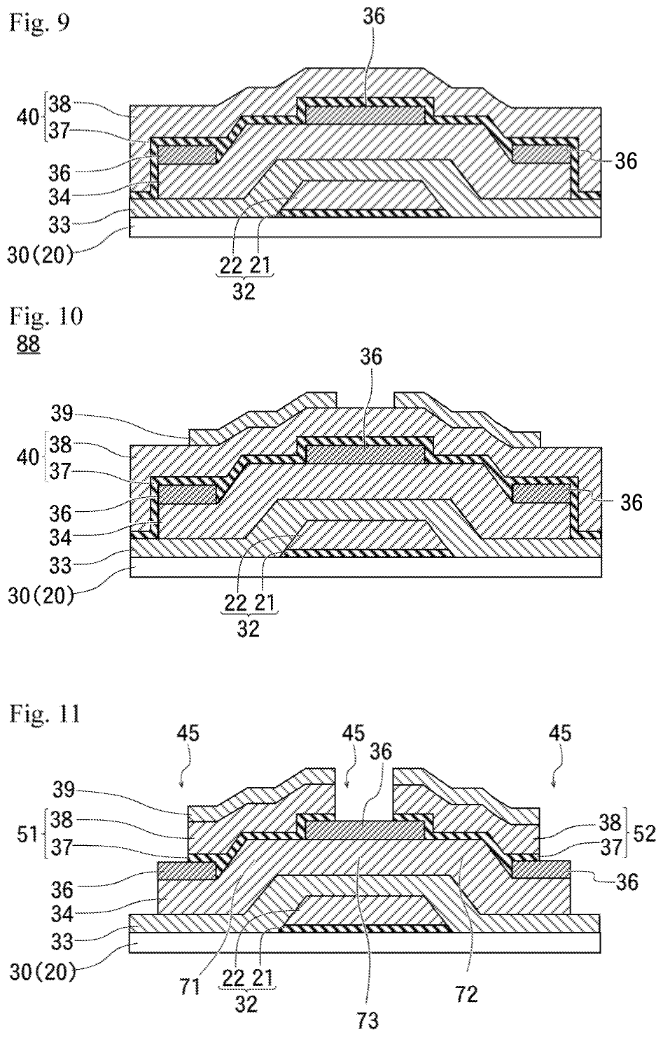

The oxygen-containing copper thin film is a thin film containing copper as a main component and containing oxygen, and the copper thin film is a thin film containing copper as a main component and having an oxygen content and a resistance lower than those of the oxygen-containing copper thin film. The first electrode layer 51 and the second electrode layer 52 constitute a stack-type electrode layer 40 containing copper as a main component, having a two-layer structure, and described below with reference to FIGS. 9 and 10.

A recess 55 is provided between the first electrode layer 51 and the second electrode layer 52, the first electrode layer 51 and the second electrode layer 52 are separated from each other by the recess 55, and the first electrode layer 51 and the second electrode layer 52 are respectively in contact with the semiconductor layer 34 to be electrically connected to the semiconductor layer 34.

The recess 55 is formed by partially etching the stack-type electrode layer 40 having the two-layer structure constituting the first electrode layer 51 and the second electrode layer 52. A stopper layer 36 is disposed below the stack-type electrode layer 40 formed in a part in which the recess 55 is formed, and when the stack-type electrode layer 40 is removed by etching, the semiconductor layer 34 is covered with the stopper layer 36 on a bottom surface of the recess 55, such that the semiconductor layer 34 is not exposed and the stopper layer 36 is exposed.

A protective film 41 is formed on the first electrode layer 51, the second electrode layer 52, and the recess 55 that is between the first electrode layer 51 and the second electrode layer 52, in order to prevent permeation of moisture and the like, and the stopper layer 36 on the semiconductor layer 34 and the protective film 41 formed in the recess 55 are in contact with each other on a part of the bottom surface of the recess 55.

A transparent lower wiring layer 42 extending up to the liquid crystal display portion 14 is in contact with the second electrode layer 52, and the second electrode layer 52 and the lower wiring layer 42 are electrically connected to each other.

At least a part of the lower wiring layer 42 positioned in the liquid crystal display portion 14 is used as the pixel electrode layer 82 having a large area, a liquid crystal layer 83 is disposed on the pixel electrode layer 82, and a transparent upper electrode 81 is disposed on the liquid crystal layer 83. Therefore, the liquid crystal layer 83 is interposed between the transparent pixel electrode layer 82 and upper electrode 81.

When a voltage between the pixel electrode layer 82 and the upper electrode 81 changes, a voltage applied to the liquid crystal layer 83 is changed, such that a direction of polarization of light that penetrates the liquid crystal layer 83 changes, therefore, when light emitted from a light source penetrates the liquid crystal layer 83, the direction of the polarization of the light that penetrates the liquid crystal layer 83 changes due to the change in the voltage between the pixel electrode layer 82 and the upper electrode 81.

A polarizing filter 85 is disposed on the upper electrode 81, such that the light that was emitted from the light source and that penetrated the liquid crystal layer 83 and the upper electrode 81 is incident on the polarizing filter 85.

When the direction of the polarization of the light changes, a relationship between the direction of the polarization of the light and a direction of polarization of the polarizing filter 85 changes, such that light that penetrated the polarizing filter 85 is shielded by the polarizing filter 85 or light shielded by the polarizing filter 85 penetrates through the polarizing filter 85.

As described above, by changing the direction of the polarization of the liquid crystal layer 83, it is possible to switch between a light penetrating state and a light shielding state.

The pixel electrode layer 82 is electrically connected to the first electrode layer 51 or the second electrode layer 52, and conduction and interruption of the semiconductor element 11 can be switched by controlling potentials between the first and second electrode layers 51 and 52 and the gate electrode layer 32. Therefore, it is possible to control the light penetrating state and the light shielding state by controlling the conduction and the interruption of the semiconductor element 11.

A plurality of liquid crystal display portions 14 are provided on the resin substrate 30, pixel electrode layers 82 are disposed in the liquid crystal display portions 14, respectively, and the liquid crystal layer 83, the upper electrode 81, and the polarizing filter 85 are disposed on each pixel electrode layer 82.

Different semiconductor elements 11 are connected to the respective pixel electrode layers 82, and directions of polarization of the liquid crystal layers 83 on the respective pixel electrode layers 82 are controlled by controlling conduction and interruption of the semiconductor elements 11 to which the pixel electrode layers 82 are connected, such that light penetrating states and light shielding states are controlled on the respective pixel electrode layers 82 and a display on a screen is performed.

The display device according to the present embodiment also includes an organic electroluminescence (EL) display device using an organic EL layer. In the organic EL display device, for example, instead of the liquid crystal layer 83, an organic EL layer is disposed on a surface of the pixel electrode layer 82, and a magnitude of a voltage applied between the upper electrode 81 and the pixel electrode layer 82 each disposed on surfaces of the organic EL layer is controlled by controlling the semiconductor element 11, such that a magnitude of a current flowing through the organic EL layer changes and an amount of emitted light changes to perform a desired display. In the organic EL display device, in order to improve visibility outdoors, a polarizing filter may be used for preventing reflection of external light.

Next, a manufacturing process of the semiconductor element 11 will be described.

<Manufacturing Process of Semiconductor Element>

In this semiconductor element 11, the wiring films 31 and 32 are first formed on the resin substrate 30 by a vacuum thin film forming method such as a sputtering method or a vapor deposition method.

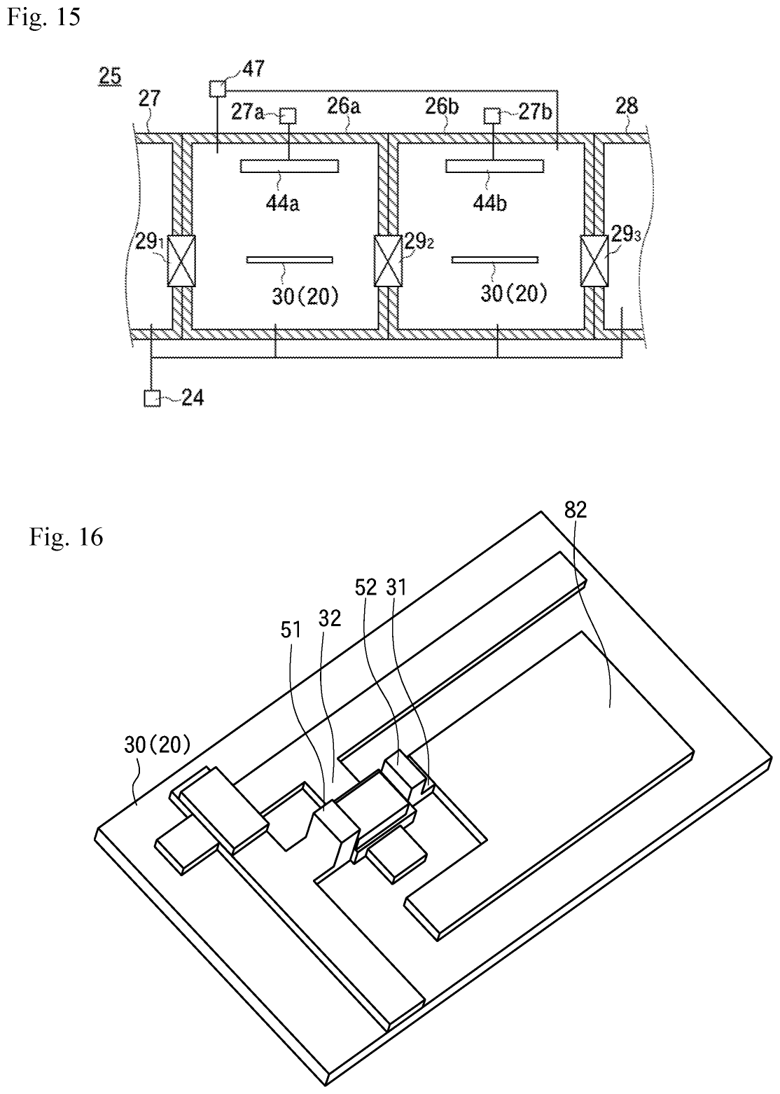

FIG. 15 shows a film forming device 25 for forming the wiring films 31 and 32, and the film forming device 25 has first and second vacuum chambers 26a and 26b. First and second targets 44a and 44b are disposed in the first and second vacuum chambers 26a and 26b, respectively.

A pretreatment chamber 27 is disposed at a former stage of the first vacuum chamber 26a, and a carry-out chamber 28 is disposed at a latter stage of the second vacuum chamber 26b. An inner part of the pretreatment chamber 27, an inner part of the first vacuum chamber 26a, an inner part of the second vacuum chamber 26b, and an inner part of the carry-out chamber 28 are connected to each other through gate valves 29₁ to 29₃, respectively.

The pretreatment chamber 27, the first and second vacuum chambers 26a and 26b, and the carry-out chamber 28 are connected to a vacuum evacuation device 24 respectively, and are vacuum-evacuated to the vacuum atmosphere by an operation of the vacuum evacuation device 24.

The gate valve 29₁ is first opened to connect the inner part of the first vacuum chamber 26a and the inner part of the pretreatment chamber 27 to each other, the resin substrate 30 positioned in the pretreatment chamber 27 is moved to the inner part of the first vacuum chamber 26a, and the gate valve 29₁ is closed.

The first target 44a in the first vacuum chamber 26a is an alloy containing copper as a main component, containing aluminum as a main additive metal in a predetermined ratio, and containing any one or two of silicon, titanium, manganese, and nickel as a sub-additive metal in a predetermined ratio.

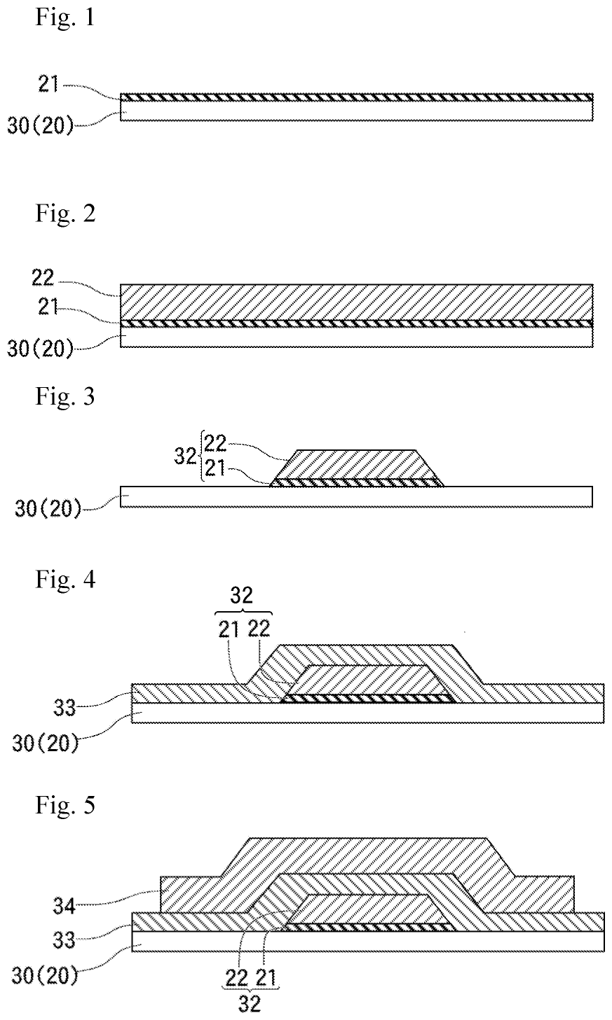

The first and second vacuum chambers 26a and 26b are connected to a gas introduction device 47, and when a sputtering gas, such as an argon gas, is introduced from the gas introduction device 47 into the first vacuum chamber 26a and a sputtering voltage is applied to the first target 44a by a sputtering power supply 27a to sputter the first target 44a, a base film 21 having the same composition as that of the first target 44a and in contact with the resin substrate 30 is formed on a surface of the resin substrate 30, as shown in FIG. 1.

When the base film 21 is formed to a predetermined thickness, the sputtering of the first target 44a is stopped, the gate valve 29₂ between the first and second vacuum chambers 26a and 26b is opened, the resin substrate 30 on which the base film 21 is formed and that is positioned in the first vacuum chamber 26a is moved to the inner part of the second vacuum chamber 26b, the gate valve 29₂ is closed, a sputtering gas is introduced into the second vacuum chamber 26b, and the second target 44b is sputtered by a sputtering power supply 27b to form a low resistance film 22 in contact with the base film 21 at a predetermined thickness on the base film 21.

The second target 44b is formed of pure copper or a copper alloy of which a copper content is higher than that of the first target 44a and conductivity is larger than that of the first target 44a, and a composition of the low resistance film 22 is the same as that of the second target 44b.

The first and second targets 44a and 44b have high copper contents, and the base film 21 and the low resistance film 22 obtained by the sputtering of the first and second targets 44a and 44b, respectively, can be patterned by the same etchant or the same etching gas.

When the low resistance film 22 is formed to a predetermined thickness, the sputtering in the second vacuum chamber 26b is stopped, the gate valve 29₃ between the second vacuum chamber 26b and the carry-out chamber 28 is opened, the resin substrate 30 on which the base film 21 and the low resistance film 22 are formed is moved from the inner part of the second vacuum chamber 26b to the inner part of the carry-out chamber 28, the gate valve 29₃ is closed, the atmosphere is introduced into the carry-out chamber 28, the resin substrate 30 is taken out from the inner part of the carry-out chamber 28 to the atmosphere, and a wiring film 32 including the patterned base film 21 and low resistance film 22 as shown in FIG. 3 is formed by a photolithography process and a single etching process.

The wiring film 32 is a gate electrode layer 32, but a wiring film 31 positioned at another place is also formed together with the gate electrode layer 32.

The surface of the resin substrate 30 is exposed at places other than places at which the wiring film 31 and the gate electrode layer 32 formed by the patterning are positioned.

Then, as shown in FIG. 4, a gate insulating film 33 formed of SiO₂, SiNx, or the like is formed on surfaces of the resin substrate 30 and the gate electrode layer 32. The gate insulating film 33 is also formed on a surface of another wiring film 31.

Then, the gate insulating film 33 is patterned in a required planar shape, and a semiconductor thin film is formed on the gate insulating film 33 and patterned to form a semiconductor layer 34 shown in FIG. 5.

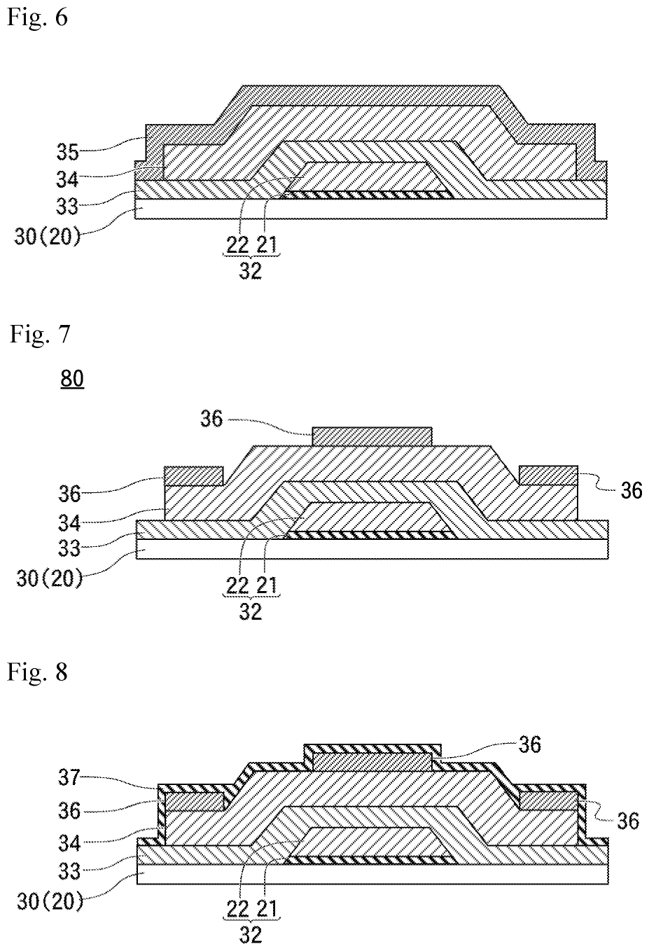

Then, as shown in FIG. 6, an oxide insulating thin film 35 is formed on a part exposed on the resin substrate 30, such as a surface of the semiconductor layer 34 or the surface of the gate insulating film 33, and the oxide insulating thin film 35 is patterned as shown in FIG. 7 to form a stopper layer 36 formed of the oxide insulating thin film.

In an object 80 to be processed in a state of FIG. 7, the stopper layer 36 covers parts of the surface of the semiconductor layer 34, and exposes the other parts.

Then, an oxygen diffusion preventing layer 37 having conductivity is formed on a surface of the object 80 to be processed, as shown in FIG. 8, and an upper electrode layer 38 having a low resistance is formed as shown in FIG. 9 to constitute a stack-type electrode layer having a two-layer structure with the oxygen diffusion preventing layer 37 and the upper electrode layer 38.

Then, as shown in FIG. 10, a patterned resist film 39 is formed on a surface of the stack-type electrode layer 40 positioned above a part that becomes a source region and a part that becomes a drain region to be described below.

When it is assumed that the resin substrate 30 and members on the resin substrate in this state are an object 88 to be processed, the object 88 to be processed is immersed in an etching solution for etching of the oxygen diffusion preventing layer 37 and the upper electrode layer 38.

In the object 88 to be processed, the upper electrode layer 38 is exposed in parts that are not covered with the resist film 39, and the exposed upper electrode layer 38 and the oxygen diffusion preventing layer 37 under the upper electrode layer 38 are etched by the etching solution, such that an opening 45 is formed in a part at which the upper electrode layer 38 and the oxygen diffusion preventing layer 37 are dissolved and removed, as shown in FIG. 11.

The stopper layer 36 is formed of a material that is not etched by the etching solution of the upper electrode layer 38 and the oxygen diffusion preventing layer 37, and the etching by the etching solution is stopped when the stopper layer 36 is exposed on a bottom surface of the opening 45.

The gate electrode layer 32 is elongated, and when a portion of the semiconductor layer 34 on one side part of the gate electrode layer 32 above the gate electrode layer 32 is referred to as a source region 71 and other portion of the semiconductor layer 34 on an opposite side part of the gate electrode layer 32 to the source region 71 above the gate electrode layer 32 is referred to as a drain region 72, the stack-type electrode layer 40 is separated into a first electrode layer 51 in contact with the source region 71 and a second electrode layer 52 in contact with the drain region 72 by this etching. A region of the semiconductor layer 34 between the source region 71 and the drain region 72 is called a control region 73 in which switching between conduction and non-conduction is performed.

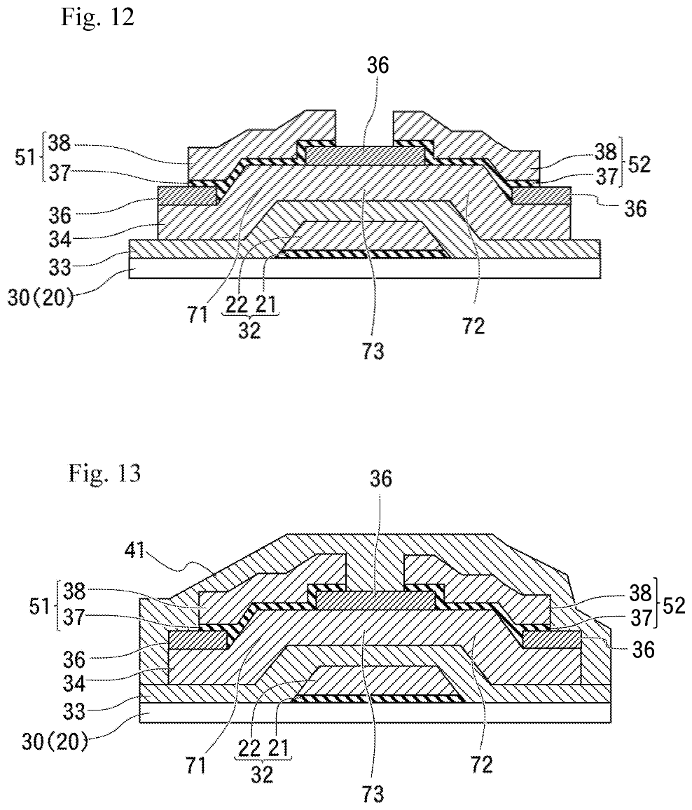

Then, the resist film 39 is removed as shown in FIG. 12, a protective film 41 made of an insulating film such as SiNx, SiO₂ or the like is formed as shown in FIG. 13, a connection hole 43 such as a via hole or a contact hole is formed in the protective film 41 as shown in FIG. 14, and a transparent lower wiring layer 42 electrically connecting the first electrode layer 51, the second electrode layer 52 or the like, exposed on a bottom surface of the connection hole 43 and an electrode layer of another element on the resin substrate 30 to each other is formed.

The gate electrode layer 32 and the first and second electrode layers 51 and 52 are in a state that voltages can be applied thereto, and the switching between the conduction and the non-conduction in the control region 73 can be controlled by the voltages between the gate electrode layer 32 and the first and second electrode layers 51 and 52, such that the semiconductor element 11 can perform operations of conduction and interruption. A liquid crystal layer 83 and an upper electrode 81 are disposed in a subsequent process, and as described above, the display is performed by conduction and interruption of a plurality of semiconductor elements 11. In a case of using an etching solution that does not erode the semiconductor layer 34, the semiconductor layer 34 can be in contact with the etching liquid, such that the stopper layer 36 is not required.

Since the base film 21 in contact with the resin substrate 30 has a strong adhesive force to the resin, the wiring films 31 and 32 (gate electrode layer 32) are not peeled from the resin substrate 30.

In addition, since the base film 21 and the low resistance film 22 contain a large amount of copper, the base film 21 and the low resistance film 22 can be etched by an etchant or an etching gas for etching copper. Therefore, the wiring films 31 and 32 can be patterned by a single etching process.

Although the manufacturing process of the semiconductor element 11 that uses the resin substrate 30 as a substrate in contact with the base film 21 has been described hereinabove, an invention relating to a semiconductor element 11 that uses a glass substrate instead of the resin substrate 30 is also included in the present embodiment.

When a base film is formed on the glass substrate 20, a sputtering gas such as argon gas is introduced from the gas introduction device 47 into the first vacuum chamber 26a, and a sputtering voltage is applied to the first target 44a by the sputtering power supply 27a to sputter the first target 44a, such that a base film 21 having the same composition as that of the first target 44a is formed in contact with a surface of the glass substrate 20 and on the surface of the glass substrate 20 disposed in the first vacuum chamber 26a.

Here, in the second vacuum chamber 26b, a low resistance film 22 having the same composition as that of the second target 44b is formed in contact with the base film 21 and on the base film 21.

In a case of the glass substrate 20, after the base film 21 is formed and before the low resistance film 22 is formed or after the base film 21 and the low resistance film 22 are formed, it is preferable that annealing for heating the glass substrate 20 and the base film 21 or annealing for heating the glass substrate 20, the base film 21, and the low resistance film 22 may be performed.

In both cases, where the annealing is performed or where the annealing is not performed, a wiring film 32 is formed by the same process as that in a case of using the resin substrate 30, and after the wiring film 32 is formed, the semiconductor element 11 according to the present embodiment having the glass substrate 20 is obtained by the same processes as those described above with reference to FIGS. 4 to 14 in the case of using the resin substrate 30.

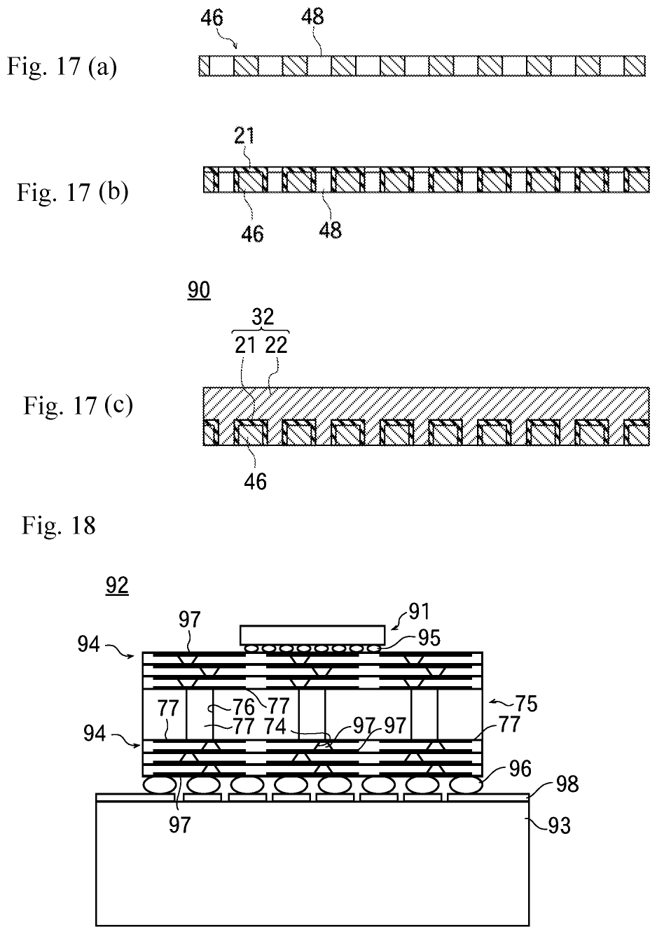

Next, another embodiment of the present invention will be described. A glass substrate 46 of FIG. 17(a) is a glass interposer, and a plurality of through-holes 48 are formed in the glass substrate 46. A base film 21 is formed on a front surface of the glass substrate 46 and inner peripheral surfaces of the through-holes 48, as shown in FIG. 17(b), by sputtering of a first target 44a. However, here, the base film 21 is not formed on a back surface of the glass substrate 46.

For example, a thickness of the base film 21 is 150 nm, an opening of each of the through-holes 48 has a circular shape with a diameter of 50 μm, and a distance between the centers of adjacent through-holes 48 is 100 μm.

Then, when the glass substrate 46 on which the base film 21 is formed is immersed in a plating solution and a copper thin film is grown on a surface of the base film 21 by an electroplating method to form a low resistance film 22, a wiring substrate 90 provided with a wiring film 32 including the base film 21 and the low resistance film 22 as shown in FIG. 17(c) is obtained.

The low resistance film 22 is formed of pure copper or a copper alloy, of which a copper content ratio is higher than that of the first target 44a and the base film 21, and conductivity of the low resistance film 22 is larger than that of the first target 44a and the base film 21, and the glass substrate 46 provided with the wiring film 32 can be mounted with a semiconductor chip and be used in order to form an electronic circuit.

In addition, since the front surface and the back surface of the glass substrate 46 can be electrically connected to each other by the low resistance film 22 filled in the through-holes 48, it is possible to electrically connect the semiconductor chip on the front surface of the glass substrate 46 and a pad at a desired position on the back surface of the glass substrate 46.

Next, a build-up substrate will be described. In FIG. 18, reference numeral 75 denotes a glass substrate in which a first through-hole 76 is formed, and a first wiring film 77 including a base film and a low resistance film having the composition described above is formed on a front surface of the glass substrate 75 and on an inner peripheral surface of the first through-hole 76. The first through-hole 76 is filled with the first wiring film 77, and the first wiring film 77 on the front surface of the glass substrate 75 and the first wiring film 77 on a back surface of the glass substrate 75 are respectively in contact with the first wiring film 77 filled in the first through-hole 76 to be electrically connected each other by the first wiring film 77 filled in the first through-hole 76.

A plurality of resin substrates 94 in which second through-holes 74 are formed are stacked on the front surface and the back surface of the glass substrate 75, such that a build-up substrate 92 including the glass substrate 75 and the resin substrates 94 stacked on and beneath the glass substrate 75 are formed.

A second wiring film 97 including a base film and a low resistance film having the composition described above is formed on a surface of each of the stacked resin substrates 94, and is also filled in the second through-holes 74. The second wiring film 97 on a surface of one resin substrate 94 and the second wiring film 97 filled in the second through-hole 74 are in contact with and electrically connected to each other.

A resin substrate 94 having a second wiring film 97 in contact with and electrically connected to the first wiring film 77 of the glass substrate 75 and a resin substrate 94 having a second wiring film 97 in contact with and electrically connected to a second wiring film 97 of an adjacent resin substrate 94 are included in the resin substrates 94 stacked on the glass substrate 75. Electrodes 95 of a semiconductor chip 91 are in contact with a second wiring film 97 of a resin substrate 94 disposed at the uppermost layer of the build-up substrate 92, and a wiring film 98 of a printed substrate 93 is connected to a second wiring film 97 of a resin substrate 94 positioned at the lowermost layer of the build-up substrate 92 by bumps 96.

According to such a configuration, the electrodes 95 of the semiconductor chip 91 mounted on the build-up substrate 92 can be connected to the wiring film 98 of the printed substrate 93 at a desired position.

### EXAMPLES

In the following Examples and Comparative Examples, InGaZnO was used for a semiconductor layer 34. A copper thin film containing oxygen was used for an oxygen diffusion preventing layer 37, and a pure copper thin film was used for an upper electrode layer 38.

First targets formed of alloys containing aluminum, which is a main additive metal, in ratios of 0, 0.5, 1.0, 2.0, 4.0, 6.0, 8.0, 9.0, and 10 wt % and containing silicon, titanium, or manganese, which is a sub-additive metal, in ratios of 0, 0.5, 1.0, 2.0, 4.0, 6.0, 8.0, 9.0, and 10 wt % or first targets formed of alloys containing aluminum, which is a main additive metal, in ratios of 0, 0.5, 1.0, 2.0, 4.0, 6.0, 8.0, 9.0, and 10 wt % and containing nickel, which is a sub-additive metal, in ratios of 0, 5, 10, 20, 30, 40, 50, 60, and 70 wt % were produced (or were attempted to be produced), respectively, on surfaces of resin substrates 30 formed of polyimide, polyethylene terephthalate (PET), or an epoxy resin and were sputtered to form base films on the surfaces of the resin substrates 30, respectively, and peel strengths were measured. Measurement results are shown in Tables 1 to 12. Components other than the main additive metal and the sub-additive metal are copper and inevitable impurities, and a content of inevitable impurities is 1 wt % or less. A composition of the base film is the same as that of the first target on which the base film is formed.

In Tables, “No Production” is a combination of a ratio of a main additive metal and a ratio of a sub-additive metal in which the first target could not be produced, and when the resin substrate 30 was formed of polyimide or an epoxy resin, “∘” is a combination of ratios in which measured values were 0.8 kgf/cm or more, “Δ” is a combination of ratios in which measured values were in the range of 0.5 kgf/cm or more and less than 0.8 kgf/cm, and “x” is a combination of ratios in which measured values were less than 0.5 kgf/cm.

When the resin substrate 30 was formed of PET, “∘” is a combination of ratios in which measured values were 0.5 kgf/cm or more, “Δ” is a combination of ratios in which measured values were 0.2 kgf/cm or more and less than 0.5 kgf/cm, and “x” is a combination of ratios in which measured values were less than 0.2 kgf/cm.

In Tables, “∘” is a combination of suitable ratios.

First, Tables 1 to 3 show a case where a sub-additive metal is silicon, and it can be seen from measurement results that an adhesive force of a base film obtained from a first target containing aluminum, which is a main additive metal, in the range of 1.0 wt % or more to 8.0 wt % or less and containing silicon, which is a sub-additive metal, in the range of 1.0 wt % or more to 8.0 wt % or less is strong.

TABLE 1
Cu—Al—Si Resin Substrate: polyimide

| | | Si(wt %) | | | | | | | | |
|---|---|---|---|---|---|---|---|---|---|---|
| | | 0 | 0.5 | 1.0 | 2.0 | 4.0 | 6.0 | 8.0 | 9.0 | 10 |
| Al | 0 | X | X | X | X | X | X | X | No | No |
| (wt %) | | | | | | | | | Production | Production |
| | 0.5 | X | X | Δ | Δ | Δ | Δ | Δ | No | No |
| | | | | | | | | | Production | Production |
| | 1.0 | X | Δ | ◯ | ◯ | ◯ | ◯ | ◯ | No | No |
| | | | | | | | | | Production | Production |
| | 2.0 | X | Δ | ◯ | ◯ | ◯ | ◯ | ◯ | No | No |
| | | | | | | | | | Production | Production |
| | 4.0 | X | Δ | ◯ | ◯ | ◯ | ◯ | ◯ | No | No |
| | | | | | | | | | Production | Production |
| | 6.0 | X | Δ | ◯ | ◯ | ◯ | ◯ | ◯ | No | No |
| | | | | | | | | | Production | Production |
| | 8.0 | X | Δ | ◯ | ◯ | ◯ | ◯ | ◯ | No | No |
| | | | | | | | | | Production | Production |
| | 9.0 | X | Δ | Δ | Δ | Δ | No | No | No | No |
| | | | | | | | Production | Production | Production | Production |
| | 10 | X | X | X | Δ | Δ | No | No | No | No |
| | | | | | | | Production | Production | Production | Production |

Peel strength result ◯: 0.8 kgf/cm or more
Δ: 0.5 to 0.8 kgf/cm
X: less than 0.5 kgf/cm

TABLE 2
Cu—Al—Si Resin Substrate: PET

| | | Si(wt %) | | | | | | | | |
|---|---|---|---|---|---|---|---|---|---|---|
| | | 0 | 0.5 | 1.0 | 2.0 | 4.0 | 6.0 | 8.0 | 9.0 | 10 |
| Al | 0 | X | X | X | X | X | X | X | No | No |
| (wt %) | | | | | | | | | Production | Production |
| | 0.5 | X | X | X | X | Δ | Δ | Δ | No | No |
| | | | | | | | | | Production | Production |
| | 1.0 | X | X | ◯ | ◯ | ◯ | ◯ | ◯ | No | No |
| | | | | | | | | | Production | Production |
| | 2.0 | X | X | ◯ | ◯ | ◯ | ◯ | ◯ | No | No |
| | | | | | | | | | Production | Production |
| | 4.0 | X | Δ | ◯ | ◯ | ◯ | ◯ | ◯ | No | No |
| | | | | | | | | | Production | Production |
| | 6.0 | X | Δ | ◯ | ◯ | ◯ | ◯ | ◯ | No | No |
| | | | | | | | | | Production | Production |
| | 8.0 | X | Δ | ◯ | ◯ | ◯ | ◯ | ◯ | No | No |
| | | | | | | | | | Production | Production |
| | 9.0 | X | Δ | Δ | Δ | Δ | No | No | No | No |
| | | | | | | | Production | Production | Production | Production |
| | 10 | X | X | X | X | X | No | No | No | No |
| | | | | | | | Production | Production | Production | Production |

Peel strength result ◯: 0.5 kgf/cm or more
Δ: 0.2 to 0.5 kgf/cm
X: less than 0.2 kgf/cm

TABLE 3
Cu—Al—Si Resin Substrate: epoxy resin

| | | Si(wt %) | | | | | | | | |
|---|---|---|---|---|---|---|---|---|---|---|
| | | 0 | 0.5 | 1.0 | 2.0 | 4.0 | 6.0 | 8.0 | 9.0 | 10 |
| Al | 0 | X | X | X | X | X | X | X | No | No |
| (wt %) | | | | | | | | | Production | Production |
| | 0.5 | X | Δ | Δ | Δ | Δ | Δ | Δ | No | No |
| | | | | | | | | | Production | Production |
| | 1.0 | X | Δ | ◯ | ◯ | ◯ | ◯ | ◯ | No | No |
| | | | | | | | | | Production | Production |
| | 2.0 | X | Δ | ◯ | ◯ | ◯ | ◯ | ◯ | No | No |
| | | | | | | | | | Production | Production |
| | 4.0 | X | Δ | ◯ | ◯ | ◯ | ◯ | ◯ | No | No |
| | | | | | | | | | Production | Production |
| | 6.0 | X | Δ | ◯ | ◯ | ◯ | ◯ | ◯ | No | No |
| | | | | | | | | | Production | Production |
| | 8.0 | X | Δ | ◯ | ◯ | ◯ | ◯ | ◯ | No | No |
| | | | | | | | | | Production | Production |
| | 9.0 | X | Δ | Δ | Δ | Δ | No | No | No | No |
| | | | | | | | Production | Production | Production | Production |
| | 10 | X | Δ | Δ | Δ | Δ | No | No | No | No |
| | | | | | | | Production | Production | Production | Production |

Peel strength result ◯: 0.8 kgf/cm or more
Δ: 0.5 to 0.8 kgf/cm
X: less than 0.5 kgf/cm

Then, Tables 4 to 6 show a case where a sub-additive metal is titanium, and it can be seen from measurement results that an adhesive force of a base film obtained from a first target containing aluminum, which is a main additive metal, in the range of 1.0 wt % or more to 8.0 wt % or less and containing titanium, which is a sub-additive metal, in the range of 1.0 wt % or more to 4.0 wt % or less is strong.

TABLE 4
Cu—Al—Ti Resin Substrate: polyimide

| | | Ti(wt %) | | | | | | | | |
|---|---|---|---|---|---|---|---|---|---|---|
| | | 0 | 0.5 | 1.0 | 2.0 | 4.0 | 6.0 | 8.0 | 9.0 | 10 |
| Al | 0 | X | X | X | X | X | No | No | No | No |
| (wt %) | | | | | | | Production | Production | Production | Production |
| | 0.5 | X | X | Δ | Δ | Δ | No | No | No | No |
| | | | | | | | Production | Production | Production | Production |
| | 1.0 | X | Δ | ◯ | ◯ | ◯ | No | No | No | No |
| | | | | | | | Production | Production | Production | Production |
| | 2.0 | X | Δ | ◯ | ◯ | ◯ | No | No | No | No |
| | | | | | | | Production | Production | Production | Production |
| | 4.0 | X | Δ | ◯ | ◯ | ◯ | No | No | No | No |
| | | | | | | | Production | Production | Production | Production |
| | 6.0 | X | Δ | ◯ | ◯ | ◯ | No | No | No | No |
| | | | | | | | Production | Production | Production | Production |
| | 8.0 | X | Δ | ◯ | ◯ | ◯ | No | No | No | No |
| | | | | | | | Production | Production | Production | Production |
| | 9.0 | X | Δ | Δ | Δ | Δ | No | No | No | No |
| | | | | | | | Production | Production | Production | Production |
| | 10 | X | Δ | Δ | Δ | Δ | No | No | No | No |
| | | | | | | | Production | Production | Production | Production |

Peel strength result ◯: 0.8 kgf/cm or more
Δ: 0.5 to 0.8 kgf/cm
X: less than 0.5 kgf/cm

TABLE 5
Cu—Al—Ti Resin Substrate: PET

| | | Ti(wt %) | | | | | | | | |
|---|---|---|---|---|---|---|---|---|---|---|
| | | 0 | 0.5 | 1.0 | 2.0 | 4.0 | 6.0 | 8.0 | 9.0 | 10 |
| Al | 0 | X | X | X | X | X | No | No | No | No |
| (wt %) | | | | | | | Production | Production | Production | Production |
| | 0.5 | X | X | Δ | Δ | Δ | No | No | No | No |
| | | | | | | | Production | Production | Production | Production |
| | 1.0 | X | Δ | ◯ | ◯ | ◯ | No | No | No | No |
| | | | | | | | Production | Production | Production | Production |
| | 2.0 | X | Δ | ◯ | ◯ | ◯ | No | No | No | No |
| | | | | | | | Production | Production | Production | Production |
| | 4.0 | X | Δ | ◯ | ◯ | ◯ | No | No | No | No |
| | | | | | | | Production | Production | Production | Production |
| | 6.0 | X | Δ | ◯ | ◯ | ◯ | No | No | No | No |
| | | | | | | | Production | Production | Production | Production |
| | 8.0 | X | Δ | ◯ | ◯ | ◯ | No | No | No | No |
| | | | | | | | Production | Production | Production | Production |
| | 9.0 | X | Δ | Δ | Δ | Δ | No | No | No | No |
| | | | | | | | Production | Production | Production | Production |
| | 10 | X | Δ | Δ | Δ | Δ | No | No | No | No |
| | | | | | | | Production | Production | Production | Production |

Peel strength result ◯: 0.5 kgf/cm or more
Δ: 0.2 to 0.5 kgf/cm
X: less than 0.2 kgf/cm

TABLE 6
Cu—Al—Ti Resin Substrate: epoxy resin

| | | Ti(wt %) | | | | | | | | |
|---|---|---|---|---|---|---|---|---|---|---|
| | | 0 | 0.5 | 1.0 | 2.0 | 4.0 | 6.0 | 8.0 | 9.0 | 10 |
| Al | 0 | X | X | X | X | X | No | No | No | No |
| (wt %) | | | | | | | Production | Production | Production | Production |
| | 0.5 | X | Δ | Δ | Δ | Δ | No | No | No | No |
| | | | | | | | Production | Production | Production | Production |
| | 1.0 | X | Δ | ◯ | ◯ | ◯ | No | No | No | No |
| | | | | | | | Production | Production | Production | Production |
| | 2.0 | X | Δ | ◯ | ◯ | ◯ | No | No | No | No |
| | | | | | | | Production | Production | Production | Production |
| | 4.0 | X | Δ | ◯ | ◯ | ◯ | No | No | No | No |
| | | | | | | | Production | Production | Production | Production |
| | 6.0 | X | Δ | ◯ | ◯ | ◯ | No | No | No | No |
| | | | | | | | Production | Production | Production | Production |
| | 8.0 | X | Δ | ◯ | ◯ | ◯ | No | No | No | No |
| | | | | | | | Production | Production | Production | Production |
| | 9.0 | X | Δ | Δ | Δ | Δ | No | No | No | No |
| | | | | | | | Production | Production | Production | Production |
| | 10 | X | Δ | Δ | Δ | Δ | No | No | No | No |
| | | | | | | | Production | Production | Production | Production |

Peel strength result ◯: 0.8 kgf/cm or more
Δ: 0.5 to 0.8 kgf/cm
X: less than 0.5 kgf/cm

In addition, Tables 7 to 9 show a case where a sub-additive metal is manganese, and it can be seen from measurement results that an adhesive force of a base film obtained from a first target containing aluminum, which is a main additive metal, in the range of 1.0 wt % or more to 8.0 wt % or less and containing manganese, which is a sub-additive metal, in the range of 1.0 wt % or more to 8.0 wt % or less is strong.

TABLE 7
Cu—Al—Mn Resin Substrate: polyimide

| | | Mn(wt %) | | | | | | | | |
|---|---|---|---|---|---|---|---|---|---|---|
| | | 0 | 0.5 | 1.0 | 2.0 | 4.0 | 6.0 | 8.0 | 9.0 | 10 |
| Al | 0 | X | X | X | X | X | X | X | No | No |
| (wt %) | | | | | | | | | Production | Production |
| | 0.5 | X | X | Δ | Δ | Δ | Δ | Δ | No | No |
| | | | | | | | | | Production | Production |
| | 1.0 | X | Δ | ◯ | ◯ | ◯ | ◯ | ◯ | No | No |
| | | | | | | | | | Production | Production |
| | 2.0 | X | Δ | ◯ | ◯ | ◯ | ◯ | ◯ | No | No |
| | | | | | | | | | Production | Production |
| | 4.0 | X | Δ | ◯ | ◯ | ◯ | ◯ | ◯ | No | No |
| | | | | | | | | | Production | Production |
| | 6.0 | X | Δ | ◯ | ◯ | ◯ | ◯ | ◯ | No | No |
| | | | | | | | | | Production | Production |
| | 8.0 | X | Δ | ◯ | ◯ | ◯ | ◯ | ◯ | No | No |
| | | | | | | | | | Production | Production |
| | 9.0 | X | Δ | Δ | Δ | Δ | No | No | No | No |
| | | | | | | | Production | Production | Production | Production |
| | 10 | X | X | X | Δ | Δ | No | No | No | No |
| | | | | | | | Production | Production | Production | Production |

Peel strength result ◯: 0.8 kgf/cm or more
Δ: 0.5 to 0.8 kgf/cm
X: less than 0.5 kgf/cm

TABLE 8
Cu—Al—Mn Resin Substrate: PET

| | | Mn(wt %) | | | | | | | | |
|---|---|---|---|---|---|---|---|---|---|---|
| | | 0 | 0.5 | 1.0 | 2.0 | 4.0 | 6.0 | 8.0 | 9.0 | 10 |
| Al | 0 | X | X | X | X | X | X | X | No | No |
| (wt %) | | | | | | | | | Production | Production |
| | 0.5 | X | X | X | X | Δ | Δ | Δ | No | No |
| | | | | | | | | | Production | Production |
| | 1.0 | X | X | ◯ | ◯ | ◯ | ◯ | ◯ | No | No |
| | | | | | | | | | Production | Production |
| | 2.0 | X | X | ◯ | ◯ | ◯ | ◯ | ◯ | No | No |
| | | | | | | | | | Production | Production |
| | 4.0 | X | Δ | ◯ | ◯ | ◯ | ◯ | ◯ | No | No |
| | | | | | | | | | Production | Production |
| | 6.0 | X | Δ | ◯ | ◯ | ◯ | ◯ | ◯ | No | No |
| | | | | | | | | | Production | Production |
| | 8.0 | X | Δ | ◯ | ◯ | ◯ | ◯ | ◯ | No | No |
| | | | | | | | | | Production | Production |
| | 9.0 | X | Δ | Δ | Δ | Δ | No | No | No | No |
| | | | | | | | Production | Production | Production | Production |
| | 10 | X | X | X | X | X | No | No | No | No |
| | | | | | | | Production | Production | Production | Production |

Peel strength result ◯: 0.5 kgf/cm or more
Δ: 0.2 to 0.5 kgf/cm
X: less than 0.2 kgf/cm

TABLE 9
Cu—Al—Mn Resin Substrate: epoxy resin

| | | Mn(wt %) | | | | | | | | |
|---|---|---|---|---|---|---|---|---|---|---|
| | | 0 | 0.5 | 1.0 | 2.0 | 4.0 | 6.0 | 8.0 | 9.0 | 10 |
| Al | 0 | X | X | X | X | X | X | X | No | No |
| (wt %) | | | | | | | | | Production | Production |
| | 0.5 | X | Δ | Δ | Δ | Δ | Δ | Δ | No | No |
| | | | | | | | | | Production | Production |
| | 1.0 | X | Δ | ◯ | ◯ | ◯ | ◯ | ◯ | No | No |
| | | | | | | | | | Production | Production |
| | 2.0 | X | Δ | ◯ | ◯ | ◯ | ◯ | ◯ | No | No |
| | | | | | | | | | Production | Production |
| | 4.0 | X | Δ | ◯ | ◯ | ◯ | ◯ | ◯ | No | No |
| | | | | | | | | | Production | Production |
| | 6.0 | X | Δ | ◯ | ◯ | ◯ | ◯ | ◯ | No | No |
| | | | | | | | | | Production | Production |
| | 8.0 | X | Δ | ◯ | ◯ | ◯ | ◯ | ◯ | No | No |
| | | | | | | | | | Production | Production |
| | 9.0 | X | Δ | Δ | Δ | Δ | No | No | No | No |
| | | | | | | | Production | Production | Production | Production |
| | 10 | X | Δ | Δ | Δ | Δ | No | No | No | No |
| | | | | | | | Production | Production | Production | Production |

Peel strength result ◯: 0.8 kgf/cm or more
Δ: 0.5 to 0.8 kgf/cm
X: less than 0.5 kgf/cm

In addition, Tables 10 to 12 show a case where a sub-additive metal is nickel, and it can be seen from measurement results that an adhesive force of a base film obtained from a first target containing aluminum, which is a main additive metal, in the range of 1.0 wt % or more to 8.0 wt % or less and containing nickel, which is a sub-additive metal, in the range of 10 wt % or more to 50 wt % or less is strong.

TABLE 10
Cu—Al—Ni Resin Substrate: polyimide

| | | Ni(wt %) | | | | | | | | |
|---|---|---|---|---|---|---|---|---|---|---|
| | | 0 | 5 | 10 | 20 | 30 | 40 | 50 | 60 | 70 |
| Al | 0 | X | X | X | X | X | X | X | Δ | Δ |
| (wt %) | 0.5 | X | X | Δ | Δ | Δ | Δ | Δ | Δ | Δ |
| | 1.0 | X | Δ | ◯ | ◯ | ◯ | ◯ | ◯ | Δ | Δ |
| | 2.0 | X | Δ | ◯ | ◯ | ◯ | ◯ | ◯ | Δ | Δ |
| | 4.0 | X | Δ | ◯ | ◯ | ◯ | ◯ | ◯ | Δ | Δ |
| | 6.0 | X | Δ | ◯ | ◯ | ◯ | ◯ | ◯ | Δ | Δ |
| | 8.0 | X | Δ | ◯ | ◯ | ◯ | ◯ | ◯ | Δ | Δ |
| | 9.0 | X | Δ | Δ | Δ | Δ | Δ | Δ | Δ | Δ |
| | 10 | X | X | X | Δ | Δ | Δ | Δ | Δ | Δ |

Peel strength result ◯: 0.8 kgf/cm or more
Δ: 0.5 to 0.8 kgf/cm
X: less than 0.5 kgf/cm

TABLE 11
Cu—Al—Ni Resin Substrate: PET

| | | Ni(wt %) | | | | | | | | |
|---|---|---|---|---|---|---|---|---|---|---|
| | | 0 | 5 | 10 | 20 | 30 | 40 | 50 | 60 | 70 |
| Al | 0 | X | X | X | X | X | X | X | Δ | Δ |
| (wt %) | 0.5 | X | X | X | X | Δ | Δ | Δ | Δ | Δ |
| | 1.0 | X | X | ◯ | ◯ | ◯ | ◯ | ◯ | Δ | Δ |
| | 2.0 | X | X | ◯ | ◯ | ◯ | ◯ | ◯ | Δ | Δ |
| | 4.0 | X | Δ | ◯ | ◯ | ◯ | ◯ | ◯ | A | Δ |
| | 6.0 | X | Δ | ◯ | ◯ | ◯ | ◯ | ◯ | Δ | Δ |
| | 8.0 | X | Δ | ◯ | ◯ | ◯ | ◯ | ◯ | Δ | Δ |
| | 9.0 | X | Δ | Δ | Δ | Δ | Δ | A | Δ | Δ |
| | 10 | X | X | X | X | Δ | Δ | Δ | Δ | Δ |

Peel strength result ◯: 0.5 kgf/cm or more
Δ: 0.2 to 0.5 kgf/cm
X: less than 0.2 kgf/cm

TABLE 12
Cu—Al—Ni Resin Substrate: epoxy resin

| | | Ni(wt %) | | | | | | | | |
|---|---|---|---|---|---|---|---|---|---|---|
| | | 0 | 5 | 10 | 20 | 30 | 40 | 50 | 60 | 70 |
| Al | 0 | X | X | X | X | X | X | X | Δ | Δ |
| (wt %) | 0.5 | X | Δ | Δ | Δ | Δ | Δ | Δ | Δ | Δ |
| | 1.0 | X | Δ | ◯ | ◯ | ◯ | ◯ | ◯ | Δ | Δ |
| | 2.0 | X | Δ | ◯ | ◯ | ◯ | ◯ | ◯ | Δ | Δ |
| | 4.0 | X | Δ | ◯ | ◯ | ◯ | ◯ | ◯ | Δ | Δ |
| | 6.0 | X | Δ | ◯ | ◯ | ◯ | ◯ | ◯ | Δ | Δ |
| | 8.0 | X | Δ | ◯ | ◯ | ◯ | ◯ | ◯ | Δ | Δ |
| | 9.0 | X | Δ | Δ | Δ | Δ | Δ | Δ | Δ | Δ |
| | 10 | X | Δ | Δ | Δ | Δ | Δ | Δ | Δ | Δ |

Peel strength result ◯: 0.8 kgf/cm or more
Δ: 0.5 to 0.8 kgf/cm
X: less than 0.5 kgf/cm

In the related art, a wiring film having a high adhesive strength to a glass substrate has been required, such that an additive chemically bonded to oxygen in the glass substrate has been added into the wiring film. However, in order to increase an adhesive strength to the resin substrate 30, an additive chemically bonded to oxygen, hydrogen, and carbon contained in a chemical structure of a resin in the resin substrate 30 is required. In particular, the sub-additive metal contained in the base films 21 of the wiring films 31 and 32 described above has a high reactivity with carbon and has a large adhesive strength to the resin substrate 30.

<Glass Substrate>

Next, first targets formed of alloys containing aluminum, which is a main additive metal, in ratios of 0, 0.5, 1.0, 2.0, 4.0, 6.0, 8.0, 9.0, and 10 wt % and containing silicon, which is a sub-additive metal, in ratios of 0, 0.5, 1.0, 2.0, 4.0, 6.0, 8.0, 9.0, and 10 wt % were produced (or were attempted to be produced), respectively, on surfaces of glass substrates 20 formed of alkali glass and having flat surfaces, and were sputtered to form base films having a thickness of 50 nm on the surfaces of the glass substrates 20, respectively. Then, second targets formed of pure copper or copper alloys of which copper contents are higher than those of the first targets and the base films 21 and of which conductivity is larger than that of the first targets and the base films 21 were sputtered to form low resistance films 22 on surfaces of the base films, respectively, and wiring films 32 in which the base films 21 and the low resistance films 22 are stacked, respectively, were formed.

Components other than the main additive metal and the sub-additive metal are copper and inevitable impurities, and a content of inevitable impurities is 1 wt % or less. A composition of the base film is the same as that of the first target on which the base film is formed.

As an evaluation of adhesion, a peel strength test was conducted under a test condition in which an adhesive tape is attached to a surface of the wiring film 32 and is then peeled from the wiring film 32.

Evaluation results of the peel strength test are shown in Table 13. As an evaluation condition, it was assumed that a defect occurred when one or more of 10×10 small pieces were peeled, and x was written in Table 13.

TABLE 13
Cu—Al—Si Glass Substrate

| | | Si(wt %) | | | | | | | | |
|---|---|---|---|---|---|---|---|---|---|---|
| | | 0 | 0.5 | 1.0 | 2.0 | 4.0 | 6.0 | 8.0 | 9.0 | 10 |
| Al | 0 | X | X | X | X | X | X | X | No | No |
| (wt %) | | | | | | | | | Production | Production |
| | 0.5 | X | ◯ | ◯ | ◯ | ◯ | ◯ | ◯ | No | No |
| | | | | | | | | | Production | Production |
| | 1.0 | X | ◯ | ◯ | ◯ | ◯ | ◯ | ◯ | No | No |
| | | | | | | | | | Production | Production |
| | 2.0 | X | ◯ | ◯ | ◯ | ◯ | ◯ | ◯ | No | No |
| | | | | | | | | | Production | Production |
| | 4.0 | X | ◯ | ◯ | ◯ | ◯ | ◯ | ◯ | No | No |
| | | | | | | | | | Production | Production |
| | 6.0 | X | ◯ | ◯ | ◯ | ◯ | ◯ | ◯ | No | No |
| | | | | | | | | | Production | Production |
| | 8.0 | X | ◯ | ◯ | ◯ | ◯ | ◯ | ◯ | No | No |
| | | | | | | | | | Production | Production |
| | 9.0 | X | ◯ | ◯ | ◯ | ◯ | No | No | No | No |
| | | | | | | | Production | Production | Production | Production |
| | 10 | X | ◯ | ◯ | ◯ | ◯ | No | No | No | No |
| | | | | | | | Production | Production | Production | Production |

◯: Peel is not generated
X: One or more squares are peeld
No production: target cannot be produced

It can be seen from Table 13 that when a content of Al is in the range of 0.5 wt % or more to 8.0 wt % or less and a content of Si is in the range of 0.5 wt % or more to 8.0 wt % or less and when a content of Al is in the range of 9.0 wt % or more to 10 wt % or less and a content of Si is in the range of 0.5 wt % or more to 4.0 wt % or less, a peel strength is high.

Next, the same first targets as those of Table 13 (first targets formed of alloys containing aluminum, which is a main additive metal, in ratios of 0, 0.5, 1.0, 2.0, 4.0, 6.0, 8.0, 9.0, and 10 wt % and containing silicon, which is a sub-additive metal, in ratios of 0, 0.5, 1.0, 2.0, 4.0, 6.0, 8.0, 9.0, and 10 wt %) were produced (or were attempted to be produced), respectively, on surfaces of the glass substrates 46 shown in FIG. 17(a), and were sputtered to form the base films 21 having a thickness of 150 nm as shown in FIG. 17(b) on the surfaces of the glass substrates 46, respectively.

A plurality of through-holes 48 are formed in the glass substrates 46, and the base films 21 are formed on inner peripheral surfaces of the through-hole 48 as well as front surfaces of the glass substrates 46. The base films 21 are not formed on back surfaces of the glass substrate 46.

The base film 21 was formed at a thickness of 150 nm. An opening of the through-hole 48 has a circular shape with a diameter of 50 μm, and a distance between the centers of adjacent through-holes 48 is 100 μm.

Then, the glass substrates 46 on which the base films 21 are formed, respectively, were immersed in a plating solution, and low resistance films 22 formed of a copper thin film having a thickness of 5 μm were formed, respectively, on surfaces of the base films 21 by an electroplating method, such that wiring films 32 each including the base film 21 and the low resistance film 22 were obtained. The low resistance film 22 is formed of pure copper or a copper alloy of which a copper content is higher than that of the first target 44a and the base film 21 and of which conductivity is larger than that of the first target 44a and the base film 21.

A peel strength test was conducted under the same test condition and evaluation condition as those of Table 13. Test results of the peel strength test are shown in Table 14.

TABLE 14
Cu—Al—Si Interposer Glass Substrate

| | | Si(wt %) | | | | | | | | |
|---|---|---|---|---|---|---|---|---|---|---|
| | | 0 | 0.5 | 1.0 | 2.0 | 4.0 | 6.0 | 8.0 | 9.0 | 10 |
| Al | 0 | X | X | X | X | X | X | X | No | No |
| (wt %) | | | | | | | | | Production | Production |
| | 0.5 | X | ◯ | ◯ | ◯ | ◯ | ◯ | ◯ | No | No |
| | | | | | | | | | Production | Production |
| | 1.0 | X | ◯ | ◯ | ◯ | ◯ | ◯ | ◯ | No | No |
| | | | | | | | | | Production | Production |
| | 2.0 | X | ◯ | ◯ | ◯ | ◯ | ◯ | ◯ | No | No |
| | | | | | | | | | Production | Production |
| | 4.0 | X | ◯ | ◯ | ◯ | ◯ | ◯ | ◯ | No | No |
| | | | | | | | | | Production | Production |
| | 6.0 | X | ◯ | ◯ | ◯ | ◯ | ◯ | ◯ | No | No |
| | | | | | | | | | Production | Production |
| | 8.0 | X | ◯ | ◯ | ◯ | ◯ | ◯ | ◯ | No | No |
| | | | | | | | | | Production | Production |
| | 9.0 | X | X | X | X | X | No | No | No | No |
| | | | | | | | Production | Production | Production | Production |
| | 10 | X | X | X | X | X | No | No | No | No |
| | | | | | | | Production | Production | Production | Production |

◯: Peel is not generated
X: One or more squares are peeld
No production: target cannot be produced

It can be seen from Table 14 that when a content of Al is in the range of 0.5 wt % or more to 8.0 wt % or less and a content of Si is in the range of 0.5 wt % or more to 8.0 wt % or less, a peel strength is high.

As described above, since the wiring film according to the present invention has a high peel strength both in a case where the substrate in contact with the base film is the resin substrate and a case where the substrate in contact with the base film is the glass substrate, a liquid crystal display device, an organic EL display device, and a semiconductor element that uses the present wiring film are also included in the present invention, similar to each wiring film. In addition, the wiring film according to the present invention has a high peel strength even with respect to a composite substrate in which glass fibers are dispersed in a resin.

### REFERENCE SIGNS LIST

10 liquid crystal display device
11 semiconductor element
30 resin substrate
31, 32 wiring film
20, 46 glass substrate
21 base film
22 low resistance film
81 upper electrode
82 pixel electrode layer
83 liquid crystal layer
85 polarizing filter

What is claimed is:

1. A liquid crystal display device comprising a resin substrate, a semiconductor element, a liquid crystal layer and a polarizing filter,
wherein a voltage applied to the liquid crystal layer is changed by conduction and interruption of the semiconductor element to control penetration of light that penetrated the liquid crystal layer through the polarizing filter,
wherein the semiconductor element comprises a semiconductor layer, a gate insulating film that is in contact with the semiconductor layer, a gate electrode layer that faces the semiconductor layer with the gate insulating film interposed therebetween and that is in contact with the gate insulating film, and first and second electrode layers that are electrically connected to the semiconductor layer by contacting with the semiconductor layer, and electrical conduction and interruption between the first electrode layer and the second electrode layer are controlled by a voltage applied to the gate electrode layer,
one or more of the gate electrode layer, the first electrode layer, and the second electrode layer are electrically connected to a wiring film that is in contact with the resin substrate,
the wiring film comprises a base film that is in contact with the resin substrate and a low resistance film that is in contact with the base film and that has a resistivity lower than that of the base film,
among elements constituting the base film, copper is contained in the largest mass ratio in the base film,
aluminum is contained as a main additive metal in a range of 1.0 wt % or more to 8.0 wt % or less, silicon is contained as a sub-additive metal in a range of 1.0 wt % or more to 8.0 wt % or less,
components that are included in the base film and that are other than the main additive metal and the sub-additive metal are copper and inevitable impurities, and the inevitable impurities are contained in a range of 1 wt % or less, in 100 wt % of the base film, and
a mass ratio of copper of the low resistance film is higher than that of the base film.

2. A liquid crystal display device comprising a resin substrate, a semiconductor element, a liquid crystal layer, and a polarizing filter,
wherein a voltage applied to the liquid crystal layer is changed by conduction and interruption of the semiconductor element to control penetration of light that penetrated the liquid crystal layer through the polarizing filter,
wherein the semiconductor element comprises a semiconductor layer, a gate insulating film that is in contact with the semiconductor layer, a gate electrode layer that faces the semiconductor layer with the gate insulating film interposed therebetween and that is in contact with the gate insulating film, and first and second electrode layers that are electrically connected to the semiconductor layer by contacting with the semiconductor layer, and electrical conduction and interruption between the first electrode layer and the second electrode layer are controlled by a voltage applied to the gate electrode layer,
one or more of the gate electrode layer, the first electrode layer, and the second electrode layer are electrically connected to a wiring film that is in contact with the resin substrate,
the wiring film comprises a base film that is in contact with the resin substrate and a low resistance film that is in contact with the base film and that has a resistivity lower than that of the base film,
among elements constituting the base film, copper is contained in the largest mass ratio in the base film,
aluminum is contained as a main additive metal in a range of 1.0 wt % or more to 8.0 wt % or less, titanium is contained as a sub-additive metal in a range of 1.0 wt % or more to 4.0 wt % or less,
components that are included in the base film and that are other than the main additive metal and the sub-additive metal are copper and inevitable impurities, and the inevitable impurities are contained in a range of 1 wt % or less, in 100 wt % of the base film, and
a mass ratio of copper of the low resistance film is higher than that of the base film.

3. A liquid crystal display device comprising a resin substrate, a semiconductor element, a liquid crystal layer and a polarizing filter,
wherein a voltage applied to the liquid crystal layer is changed by conduction and interruption of the semiconductor element to control penetration of light that penetrated the liquid crystal layer through the polarizing filter,
wherein the semiconductor element comprises a semiconductor layer, a gate insulating film that is in contact with the semiconductor layer, a gate electrode layer that faces the semiconductor layer with the gate insulating film interposed therebetween and that is in contact with the gate insulating film, and first and second electrode layers that are electrically connected to the semiconductor layer by contacting with the semiconductor layer, and electrical conduction and interruption between the first electrode layer and the second electrode layer are controlled by a voltage applied to the gate electrode layer,
one or more of the gate electrode layer, the first electrode layer, and the second electrode layer are electrically connected to a wiring film that is in contact with the resin substrate,
the wiring film comprises a base film that is in contact with the resin substrate and a low resistance film that is in contact with the base film and that has a resistivity lower than that of the base film,
any one of copper and a sub-additive metal among elements constituting the base film is contained in the largest mass ratio in the base film,
aluminum is contained as a main additive metal in a range of 1.0 wt % or more to 8.0 wt % or less, nickel is contained as the sub-additive metal in a range of 10 wt % or more to 50 wt % or less,
components that are included in the base film and that are other than the main additive metal and the sub-additive metal are copper and inevitable impurities, and inevitable impurities are contained in a range of 1 wt % or less, in 100 wt % of the base film, and
a mass ratio of copper of the low resistance film is higher than that of the base film.

4. A liquid crystal display device comprising a glass substrate, a semiconductor element, a liquid crystal layer and a polarizing filter,
wherein a voltage applied to the liquid crystal layer is changed by conduction and interruption of the semiconductor element to control penetration of light that penetrated the liquid crystal layer through the polarizing filter,
wherein the semiconductor element comprises a semiconductor layer, a gate insulating film that is in contact with the semiconductor layer, a gate electrode layer that faces the semiconductor layer with the gate insulating film interposed therebetween and that is in contact with the gate insulating film, and first and second electrode layers that are electrically connected to the semiconductor layer by contacting with the semiconductor layer, and electrical conduction and interruption between the first electrode layer and the second electrode layer are controlled by a voltage applied to the gate electrode layer,
one or more of the gate electrode layer, the first electrode layer, and the second electrode layer are electrically connected to a wiring film that is in contact with the glass substrate,
the wiring film comprises a base film that is in contact with the glass substrate and a low resistance film that is in contact with the base film and that has a resistivity lower than that of the base film,
among elements constituting the base film, copper is contained in the largest mass ratio in the base film,
aluminum is contained as a main additive metal in a range of 0.5 wt % or more to 8.0 wt % or less, silicon is contained as a sub-additive metal in a range of 0.5 wt % or more to 8.0 wt % or less,
components that are included in the base film and that are other than the main additive metal and the sub-additive metal are copper and inevitable impurities, and the inevitable impurities are contained in a range of 1 wt % or less, in 100 wt % of the base film, and
a mass ratio of copper of the low resistance film is higher than that of the base film.

5. An organic electroluminescence (EL) display device comprising a resin substrate, a semiconductor element, and an organic EL layer,
wherein a voltage applied to the organic EL layer is changed by controlling the semiconductor element, such that a magnitude of a current flowing through the organic EL layer is controlled,
wherein the semiconductor element comprises a semiconductor layer, a gate insulating film that is in contact with the semiconductor layer, a gate electrode layer that faces the semiconductor layer with the gate insulating film interposed therebetween and that is in contact with the gate insulating film, and first and second electrode layers that are electrically connected to the semiconductor layer by contacting with the semiconductor layer, and electrical conduction and interruption between the first electrode layer and the second electrode layer are controlled by a voltage applied to the gate electrode layer,
one or more of the gate electrode layer, the first electrode layer, and the second electrode layer are electrically connected to a wiring film that is in contact with the resin substrate,
the wiring film comprises a base film that is in contact with the resin substrate and a low resistance film that is in contact with the base film and that has a resistivity lower than that of the base film,
among elements constituting the base film, copper is contained in the largest mass ratio in the base film,
aluminum is contained as a main additive metal in a range of 1.0 wt % or more to 8.0 wt % or less, silicon is contained as a sub-additive metal in a range of 1.0 wt % or more to 8.0 wt % or less,
components that are included in the base film and that are other than the main additive metal and the sub-additive metal are copper and inevitable impurities, and the inevitable impurities are contained in a range of 1 wt % or less, in 100 wt % of the base film, and
a mass ratio of copper of the low resistance film is higher than that of the base film.

6. An organic EL display device comprising a resin substrate, a semiconductor element, and an organic EL layer,
wherein a voltage applied to the organic EL layer is changed by controlling the semiconductor element, such that a magnitude of a current flowing through the organic EL layer is controlled,
wherein the semiconductor element comprises a semiconductor layer, a gate insulating film that is in contact with the semiconductor layer, a gate electrode layer that faces the semiconductor layer with the gate insulating film interposed therebetween and that is in contact with the gate insulating film, and first and second electrode layers that are electrically connected to the semiconductor layer by contacting with the semiconductor layer, and electrical conduction and interruption between the first electrode layer and the second electrode layer are controlled by a voltage applied to the gate electrode layer,
one or more of the gate electrode layer, the first electrode layer, and the second electrode layer are electrically connected to a wiring film that is in contact with the resin substrate,
the wiring film comprises a base film that is in contact with the resin substrate and a low resistance film that is in contact with the base film and that has a resistivity lower than that of the base film,
among elements constituting the base film, copper is contained in the largest mass ratio in the base film,
aluminum is contained as a main additive metal in a range of 1.0 wt % or more to 8.0 wt % or less, titanium is contained as a sub-additive metal in a range of 1.0 wt % or more to 4.0 wt % or less,
components that are included in the base film and that are other than the main additive metal and the sub-additive metal are copper and inevitable impurities, and the inevitable impurities are contained in a range of 1 wt % or less, in 100 wt % of the base film, and
a mass ratio of copper of the low resistance film is higher than that of the base film.

7. An organic EL display device comprising a resin substrate, a semiconductor element, and an organic EL layer,
wherein a voltage applied to the organic EL layer is changed by controlling the semiconductor element, such that a magnitude of a current flowing through the organic EL layer is controlled,
wherein the semiconductor element comprises a semiconductor layer, a gate insulating film that is in contact with the semiconductor layer, a gate electrode layer that faces the semiconductor layer with the gate insulating film interposed therebetween and that is in contact with the gate insulating film, and first and second electrode layers that are electrically connected to the semiconductor layer by contacting with the semiconductor layer, and electrical conduction and interruption between the first electrode layer and the second electrode layer are controlled by a voltage applied to the gate electrode layer,
one or more of the gate electrode layer, the first electrode layer, and the second electrode layer are electrically connected to a wiring film that is in contact with the resin substrate,
the wiring film comprises a base film that is in contact with the resin substrate and a low resistance film that is in contact with the base film and that has a resistivity lower than that of the base film,
any one of copper and a sub-additive metal among elements constituting the base film is contained in the largest mass ratio in the base film,
aluminum is contained as a main additive metal in a range of 1.0 wt % or more to 8.0 wt % or less, nickel is contained as the sub-additive metal in a range of 10 wt % or more to 50 wt % or less,
components that are included in the base film and that are other than the main additive metal and the sub-additive metal are copper and inevitable impurities, and the inevitable impurities are contained in a range of 1 wt % or less, in 100 wt % of the base film, and
a mass ratio of copper of the low resistance film is higher than that of the base film.

8. An organic EL display device comprising a glass substrate, a semiconductor element, and an organic EL layer,
wherein a voltage applied to the organic EL layer is changed by controlling the semiconductor element, such that a magnitude of a current flowing through the organic EL layer is controlled,
wherein the semiconductor element comprises a semiconductor layer, a gate insulating film that is in contact with the semiconductor layer, a gate electrode layer that faces the semiconductor layer with the gate insulating film interposed therebetween and that is in contact with the gate insulating film, and first and second electrode layers that are electrically connected to the semiconductor layer by contacting with the semiconductor layer, and electrical conduction and interruption between the first electrode layer and the second electrode layer are controlled by a voltage applied to the gate electrode layer,
one or more of the gate electrode layer, the first electrode layer, and the second electrode layer are electrically connected to a wiring film that is in contact with the glass substrate,
the wiring film comprises a base film that is in contact with the glass substrate and a low resistance film that is in contact with the base film and that has a resistivity lower than that of the base film,
among elements constituting the base film, copper is contained in the largest mass ratio in the base film,
aluminum is contained as a main additive metal in a range of 0.5 wt % or more to 8.0 wt % or less, silicon is contained as a sub-additive metal in a range of 0.5 wt % or more to 8.0 wt % or less,
components that are included in the base film and that are other than the main additive metal and the sub-additive metal are copper and inevitable impurities, and the inevitable impurities are contained in a range of 1 wt % or less, in 100 wt % of the base film, and
a mass ratio of copper of the low resistance film is higher than that of the base film.

9. A semiconductor element comprising a semiconductor layer, a gate insulating film that is in contact with the semiconductor layer, a gate electrode layer that faces the semiconductor layer with the gate insulating film interposed therebetween and that is in contact with the gate insulating film and first and second electrode layers that are electrically connected to the semiconductor layer by contacting with the semiconductor layer,
wherein electrical conduction and interruption between the first electrode layer and the second electrode layer are controlled by a voltage applied to the gate electrode layer,
one or more of the gate electrode layer, the first electrode layer, and the second electrode layer are electrically connected to a wiring film that is in contact with a resin substrate,
the wiring film comprises a base film that is in contact with the resin substrate and a low resistance film that is in contact with the base film and that has a resistivity lower than that of the base film,
among elements constituting the base film, copper is contained in the largest mass ratio in the base film,
aluminum is contained as a main additive metal in a range of 1.0 wt % or more to 8.0 wt % or less, silicon is contained as a sub-additive metal in a range of 1.0 wt % or more to 8.0 wt % or less,
components that are included in the base film and that are other than the main additive metal and the sub-additive metal are copper and inevitable impurities, and the inevitable impurities are contained in a range of 1 wt % or less, in 100 wt % of the base film, and
a mass ratio of copper of the low resistance film is higher than that of the base film.

10. A semiconductor element comprising a semiconductor layer, a gate insulating film that is in contact with the semiconductor layer, a gate electrode layer that faces the semiconductor layer with the gate insulating film interposed therebetween and that is in contact with the gate insulating film and first and second electrode layers that are electrically connected to the semiconductor layer by contacting with the semiconductor layer,
wherein electrical conduction and interruption between the first electrode layer and the second electrode layer are controlled by a voltage applied to the gate electrode layer,
one or more of the gate electrode layer, the first electrode layer, and the second electrode layer are electrically connected to a wiring film that is in contact with a resin substrate,
the wiring film comprises a base film that is in contact with the resin substrate and a low resistance film that is in contact with the base film and that has a resistivity lower than that of the base film,
among elements constituting the base film, copper is contained in the largest mass ratio in the base film,
aluminum is contained as a main additive metal in a range of 1.0 wt % or more to 8.0 wt % or less, titanium is contained as a sub-additive metal in a range of 1.0 wt % or more to 4.0 wt % or less,
components that are included in the base film and that are other than the main additive metal and the sub-additive metal are copper and inevitable impurities, and the inevitable impurities are contained in a range of 1 wt % or less, in 100 wt % of the base film, and
a mass ratio of copper of the low resistance film is higher than that of the base film.

11. A semiconductor element comprising a semiconductor layer, a gate insulating film that is in contact with the semiconductor layer, a gate electrode layer that faces the semiconductor layer with the gate insulating film interposed therebetween and that is in contact with the gate insulating film and first and second electrode layers that are electrically connected to the semiconductor layer by contacting with the semiconductor layer,
wherein electrical conduction and interruption between the first electrode layer and the second electrode layer are controlled by a voltage applied to the gate electrode layer,
one or more of the gate electrode layer, the first electrode layer, and the second electrode layer are electrically connected to a wiring film that is in contact with a resin substrate,
the wiring film comprises a base film that is in contact with the resin substrate and a low resistance film that is in contact with the base film and that has a resistivity lower than that of the base film,
any one of copper and a sub-additive metal among elements constituting the base film is contained in the largest mass ratio in the base film,
aluminum is contained as a main additive metal in a range of 1.0 wt % or more to 8.0 wt % or less, nickel is contained as the sub-additive metal in a range of 10 wt % or more to 50 wt % or less,
components that are included in the base film and that are other than the main additive metal and the sub-additive metal are copper and inevitable impurities, and the inevitable impurities are contained in a range of 1 wt % or less, in 100 wt % of the base film, and
a mass ratio of copper of the low resistance film is higher than that of the base film.

12. A wiring film fixed to a resin substrate comprising a base film that is in contact with the resin substrate and a low resistance film that is in contact with the base film and that has a resistivity lower than that of the base film,
wherein among elements constituting the base film, copper is contained in the largest mass ratio in the base film,
aluminum is contained as a main additive metal in a range of 1.0 wt % or more to 8.0 wt % or less, silicon is contained as a sub-additive metal in a range of 1.0 wt % or more to 8.0 wt % or less,
components that are included in the base film and that are other than the main additive metal and the sub-additive metal are copper and inevitable impurities, and the inevitable impurities are contained in a range of 1 wt % or less, in 100 wt % of the base film, and
a mass ratio of copper of the low resistance film is higher than that of the base film.

13. A wiring film fixed to a resin substrate, comprising a base film that is in contact with the resin substrate and a low resistance film that is in contact with the base film and that has a resistivity lower than that of the base film,
wherein among elements constituting the base film, copper is contained in the largest mass ratio in the base film,
aluminum is contained as a main additive metal in a range of 1.0 wt % or more to 8.0 wt % or less, titanium is contained as a sub-additive metal in a range of 1.0 wt % or more to 4.0 wt % or less,
components that are included in the base film and that are other than the main additive metal and the sub-additive metal are copper and inevitable impurities, and the inevitable impurities are contained in a range of 1 wt % or less, in 100 wt % of the base film, and
a mass ratio of copper of the low resistance film is higher than that of the base film.

14. A wiring film fixed to a resin substrate, comprising a base film that is in contact with the resin substrate and a low resistance film that is in contact with the base film and that has a resistivity lower than that of the base film,
wherein any one of copper and a sub-additive metal among elements constituting the base film is contained in the largest mass ratio in the base film,
aluminum is contained as a main additive metal in a range of 1.0 wt % or more to 8.0 wt % or less, nickel is contained as the sub-additive metal in a range of 10 wt % or more to 50 wt % or less,
components that are included in the base film and that are other than the main additive metal and the sub-additive metal are copper and inevitable impurities, and the inevitable impurities are contained in a range of 1 wt % or less, in 100 wt % of the base film, and
a mass ratio of copper of the low resistance film is higher than that of the base film.

15. A wiring film fixed to a glass substrate, comprising a base film that is in contact with the glass substrate and a low resistance film that is in contact with the base film and that has a resistivity lower than that of the base film,
wherein, among elements constituting the base film, copper is contained in the largest mass ratio in the base film,
aluminum is contained as a main additive metal in a range of 0.5 wt % or more to 8.0 wt % or less, silicon is contained as a sub-additive metal in a range of 0.5 wt % or more to 8.0 wt % or less,
components that are included in the base film and that are other than the main additive metal and the sub-additive metal are copper and inevitable impurities, and the inevitable impurities are contained in a range of 1 wt % or less, in 100 wt % of the base film, and
a mass ratio of copper of the low resistance film is higher than that of the base film.

16. A wiring film fixed to a glass substrate in which a plurality of through-holes are formed, comprising a base film that is in contact with a surface of the glass substrate and inner peripheral surfaces of the through-holes and a low resistance film that is in contact with the base film and that has a resistivity lower than that of the base film,
wherein, among elements constituting the base film, copper is contained in the largest mass ratio in the base film,
aluminum is contained as a main additive metal in a range of 0.5 wt % or more to 8.0 wt % or less, silicon is contained as a sub-additive metal in a range of 0.5 wt % or more to 8.0 wt % or less,
components that are included in the base film and that are other than the main additive metal and the sub-additive metal are copper and inevitable impurities, and the inevitable impurities are contained in a range of 1 wt % or less, in 100 wt % of the base film,
a mass ratio of copper of the low resistance film is higher than that of the base film, and
in at least parts of the low resistance film, a part that is disposed on a front surface of the glass substrate and a part that is in contact with the base film in the through-holes and that fills the through-holes are in contact with each other.

17. A wiring substrate comprising a glass substrate in which a plurality of through-holes are formed, and
a wiring film that is provided on the glass substrate,
wherein the wiring film comprises a base film that is in contact with a surface of the glass substrate and inner peripheral surfaces of the through-holes and a low resistance film that is in contact with the base film and that has a resistivity lower than that of the base film,
among elements constituting the base film, copper is contained in the largest mass ratio in the base film,
aluminum is contained as a main additive metal in a range of 0.5 wt % or more to 8.0 wt % or less, silicon is contained as a sub-additive metal in a range of 0.5 wt % or more to 8.0 wt % or less,
components that are included in the base film and that are other than the main additive metal and the sub-additive metal are copper and inevitable impurities, and the inevitable impurities are contained in a range of 1 wt % or less, in 100 wt % of the base film,
a mass ratio of copper of the low resistance film is higher than that of the base film,
inner portions of the through-holes are filled with the low resistance film in contact with the base film in the through-holes, and
in at least parts of the low resistance film, a part that is disposed on a front surface of the glass substrate and a part that is in contact with the base film in the through-holes and that fills the through-holes are in contact with each other.

18. A target of a sputtering device that forms a base film in contact with a resin substrate of a wiring film fixed to a resin substrate,
wherein aluminum is contained as a main additive metal in a range of 1.0 wt % or more to 8.0 wt % or less, silicon is contained as a sub-additive metal in a range of 1.0 wt % or more to 8.0 wt % or less, and
components that are included in the target and that are other than the main additive metal and the sub-additive metal are copper and inevitable impurities, and the inevitable impurities are contained in a range of 1 wt % or less, in 100 wt % of the target.

19. A target of a sputtering device that forms a base film in contact with a resin substrate of a wiring film fixed to a resin substrate,
wherein aluminum is contained as a main additive metal in a range of 1.0 wt % or more to 8.0 wt % or less, titanium is contained as a sub-additive metal in a range of 1.0 wt % or more to 4.0 wt % or less, and
components that are included in the target and that are other than the main additive metal and the sub-additive metal are copper and inevitable impurities, and the inevitable impurities are contained in a range of 1 wt % or less, in 100 wt % of the target.

20. A target of a sputtering device that forms a base film in contact with a resin substrate of a wiring film fixed to a resin substrate,
wherein aluminum is contained as a main additive metal in a range of 1.0 wt % or more to 8.0 wt % or less, nickel is contained as a sub-additive metal in a range of 10 wt % or more to 50 wt % or less and,
components that are included in the target and that are other than the main additive metal and the sub-additive metal are copper and inevitable impurities, and the inevitable impurities are contained in a range of 1 wt % or less, in 100 wt % of the target.
